(19) United States
(12) Patent Application Publication
(10) Pub. No.: US 2025/0180638 A1
(43) Pub. Date: Jun. 5, 2025

(54) AUTOMATED TEST EQUIPMENT, METHOD FOR TESTING A DEVICE UNDER TEST AND COMPUTER PROGRAM USING AN ITERATIVE APPROACH TO OBTAIN TEMPERATURE CONTROL INSTRUCTIONS

(71) Applicant: Advantest Corporation, Tokyo (JP)

(72) Inventor: Natan CHEJANOVSKY, Stuttgart (DE)

(21) Appl. No.: 19/050,915

(22) Filed: Feb. 11, 2025

Related U.S. Application Data
(63) Continuation of application No. PCT/EP2022/078454, filed on Oct. 12, 2022.

(30) Foreign Application Priority Data
Aug. 12, 2022 (EP) 22 190 322.2

(51) Int. Cl. G01R 31/28

(52) U.S. Cl. CPC G01R 31/2875; G01R 31/2834; G01R 31/2877

(57) ABSTRACT

An automated test equipment, ATE, for testing a device under test, DUT, is configured to obtain a testing profile indicating an evolution of a DUT temperature during an execution of a given test flow.

The automated test equipment is configured to analyze the testing profile, in order determine an information describing a plurality of temperature peaks.

The automated test equipment is configured to obtain a plurality of temperature control instructions for an execution of a test flow on the basis of the information describing the plurality of temperature peaks.

Moreover, the automated test equipment is configured to iteratively obtain the temperature control instructions.

### CROSS-REFERENCE TO RELATED APPLICATIONS

This application is a continuation of copending International Application No. PCT/EP2022/078454, filed Oct. 12, 2022, which is incorporated herein by reference in its entirety, and additionally claims priority from European Application No. EP 22190322.2, filed Aug. 12, 2022, which is also incorporated herein by reference in its entirety.

Embodiments according to the invention are related to an automated test equipment (ATE), for testing a device under test.

Further embodiments according to the invention are related to a method for testing a device under test.

Further embodiments according to the invention are related to a computer program for performing the method.

Embodiments according to the invention are related to concepts for an active temperature control for a test of devices under test (DUT).

### BACKGROUND OF THE INVENTION

Nowadays, integrated circuits are used in many different types of equipment, ranging from computers over mobile communication devices up to industrial equipment and automotive applications.

Even though the fabrication technology has made big progress over several decades, it is still needed to ensure the quality of the produced devices (e.g. integrated circuits) using a testing step which follows the production. The testing step can be performed before a packaging or after a packaging.

Furthermore, it should be noted that even nowadays thermal effects have a strong impact on the performance of devices, such that it is desirable to perform the testing of the devices under well-controlled thermal conditions. For example, it may be desirable to test the devices under test at different temperatures and/or to ensure that a temperature of the devices under test reliably lies within a predetermined range during a test. In the following some motivation will be described (e.g. motivation for using a thermal control or even an active thermal control (ATC) in a test equipment).

In some cases, numerous channels (or parallel components) on a device under test (DUT) are tested in parallel (e.g. central processing unit CPU/graphics processing unit GPU/accelerated processing units APUs), deviating from the original device use model. In other words, for example, during a testing of a device under test, a larger number of processing units may be operated in parallel when compared to a “normal” operation of the device under test, e.g. to increase a speed of test.

Moreover, DUT complexity is increasing with circuitry size being reduced.

These (e.g. these impacting factors) can cause excess heat to accumulate, resulting in a large temperature rise (e.g. during a testing of the device under test).

Accordingly, DUT operating conditions could be breached, impacting yield. Moreover, faulty circuits can give rise to thermal excursions, whose source needs to be pin-pointed quickly.

To conclude, in many testing applications, there is a motivation to control the temperature of the device under test.

In view of the above discussion, there is a desire to have a concept for a testing of devices under test, which provides for a good comprise between a control of a temperature, a user friendliness, a computational complexity and an implementation effort.

### SUMMARY

An embodiment relates to an automated test equipment, ATE, for testing a device under test, DUT, wherein the automated test equipment is configured to obtain a testing profile indicating an evolution of a DUT temperature during an execution of a given test flow; wherein the automated test equipment is configured analyze the testing profile, in order determine an information describing a plurality of temperature peaks; and wherein the automated test equipment is configured to obtain a plurality of temperature control instructions for an execution of a test flow on the basis of the information describing the plurality of temperature peaks; wherein the automated test equipment is configured to iteratively obtain the temperature control instructions.

Another embodiment relates to a method for testing a device under test, DUT, wherein the method includes obtaining a testing profile indicating an evolution of a DUT temperature during an execution of a given test flow; wherein the method includes analyzing the testing profile, in order determine an information describing a plurality of temperature peaks; and wherein the method includes obtaining a plurality of temperature control instructions for an execution of a test flow on the basis of the information describing the plurality of temperature peaks; and wherein the method includes iteratively obtaining the temperature control instructions.

Another embodiment relates to a non-transitory digital storage medium having a computer program stored thereon to perform the method for testing a device under test, DUT, when said computer program is run by a computer.

An embodiment according to the invention creates an automated test equipment, ATE, for testing a device under test, DUT. The automated test equipment is configured to obtain a testing profile (e.g. a DUT thermal profile) indicating an evolution of a DUT temperature during an execution of a given test flow. The automated test equipment is configured (e.g. automatically) analyze the testing profile, in order determine an information describing a plurality of (e.g. significant) temperature peaks (e.g. an information describing a peak time, and/or a peak duration, and/or a peak amplitude, and/or a fitting quality) (wherein peaks may, for example, comprise peaks in a direction towards higher temperature and peaks in a direction towards lower temperatures) (e.g. using a fitting approach; e.g. a curve fitting), and the automated test equipment is configured to obtain a plurality of temperature control instructions (e.g. cooling instructions or heating instructions) (e.g. defining a timing of a cooling, and optionally describing a cooling strength or a heating strength) for an execution of a test flow on the basis of the information describing the plurality of temperature peaks. The automated test equipment is configured to iteratively obtain (e.g. determine) the temperature control instructions.

This automated test equipment is based on the finding that information describing a plurality of temperature peaks may be obtained with a good reliability and also with a good accuracy on the basis of a testing profile indicating an evolution of a DUT temperature during an execution of a given test flow, wherein an iterative approach allows for a gradual improvement (refinement) of the resulting temperature control instructions.

It has been found that the key parameters of the temperature peaks can be obtained with good accuracy using such a procedure. Furthermore, the resulting temperature control instructions (cooling instructions or heating instructions) may be adapted (or may be well suited) for compensating thermal peaks during a real test execution. For example, using such an approach one or more parameters of the temperature control instructions may be determined with good accuracy.

By iteratively determining the temperature control instructions, it is possible to refine the temperature control instructions which have been obtained in a previous processing (or processing step). For example, a first set of temperature control instructions (also designated as initial set of temperature control instructions) can be obtained on the basis of a testing profile (“initial testing profile”), which has been obtained without any cooling, or which has been obtained using a constant cooling, or which has been obtained using a manually defined cooling profile. Thus, the “first” testing profile (or “initial testing profile”) may represent an evolution of the temperature of the device under test, which is obtained without the usage of an active temperature control (or at least without the usage of an active temperature control that is adapted to an actual, measured evolution of the DUT temperature or that is determined on the basis of the actual, measured DUT temperature). Accordingly, initial temperature control instructions can be derived on the basis of this “first” or “initial” testing profile.

Subsequently, a test (or test flow) can be run, wherein in this test run (or test flow run), the initial temperature control instructions generated on the basis of the initial (measured) testing profile may be applied, and an updated (e.g. improved) (measured) testing profile may be obtained. In the updated (measured) testing profile, typically some of the temperature peaks that have been present in the initial testing profile may be significantly reduced, or even eliminated, due to the execution of the (previously determined) temperature control instructions (which are, for example, determined in a first iteration).

However, remaining temperature peaks within the updated (measured) testing profile may be evaluated obtain improved (refined) the temperature control instructions, for example, by changing one or more parameters of the temperature control instructions and/or by replacing one temperature control instruction (e.g. out of the initial temperature control instructions) by another temperature control instruction (e.g. having different parameters and/or a different position within a test flow). Moreover, additional temperature control instructions could also be added on the basis of the updated testing profile. Accordingly, the quality of the temperature control (or of the temperature control instructions) can be improved iteratively, wherein, for example, a degradation of the test (e.g. of the execution of a test flow), which may be caused by the lack of an adaptive temperature control (or of a well-adapted active temperature control that is based on measure values) during the execution of the initial test may be overcome by the improved test (using the “first” or “initial” set of temperature control instructions). Consequently, the testing may, for example, step-wisely approximate ideal conditions.

Moreover, it has been found that the iterative approach significantly outperforms simulation approaches, since it is typically very difficult to precisely simulate a thermal behavior of a device under test during a test flow.

Moreover, it has been found that the iterative approach results in reliable (step-wisely improved) (measurement-based) temperature control instructions, since it has been recognized that the initial execution of a test flow (without active temperature control, or without measurement-based active temperature control) typically deviates significantly (e.g., with respect to a timing) from a subsequent test execution, e.g. executed using the initial (measurement-based) temperature control instructions.

To conclude, it has been found that the iterative obtaining of the temperature control instructions using multiple executions of a test flow, wherein temperature control instructions (or, more precisely, parameters of the temperature control instructions) are iteratively improved in multiple passes, results in highly reliable temperature control instructions.

In an embodiment, the automated test equipment is configured to re-execute a determination of a plurality of temperature control instructions on the basis a testing profile (e.g. to re-execute an analysis of a current testing profile, in order determine an information describing a plurality of temperature peaks, and an obtaining of a plurality of temperature control instructions for an execution of a test flow on the basis of a current information describing the plurality of temperature peaks) at least one time. Moreover, in this embodiment, the automated test equipment is configured to use (e.g. apply) previously determined temperature control instructions (e.g. temperature control instructions determined in a previous iteration; e.g. temperature control instructions determined in a previous determination of a plurality of temperature control instructions on the basis of a previous testing profile) when determining a testing profile for a current iteration (e.g. when determining a testing profile that is to be used in the current iteration).

It has been found that a re-execution of the determination of the plurality of temperature control instructions allows for a multi-step improvement of the temperature control instructions on the basis of measured temperature profiles. For example, in the first iteration, a very inaccurate temperature control (e.g. a temperature control which is not based on measurements of the DUT temperature, but which may, for example, be based on simple assumptions and/or on a DUT simulation only) may be used, such that the testing profile evaluated in the first iteration may be determine din the presence of relatively large deviations of the DUT temperature from a target value. However, it has been found that the temperature control instructions obtained in this first iteration are typically already suited to provide for a reasonably good temperature control. Thus, in the first re-execution of the determination of the temperature control instructions (second iteration), the (new, updated) testing profile is already based on the measurement-based previously determined temperature control instructions, and therefore well-describes imperfections of the DUT temperature caused by the still somewhat inappropriate temperature control instructions (determined earlier in the first iteration). Accordingly, in the first re-execution of the determination of the temperature control instructions (second iteration), improved (measurement-based) temperature control instructions can be obtained, which typically bring along a better active temperature control than the (initial) temperature control instructions derived in the first iteration. To conclude, it has been found that a re-execution of the determination of the plurality of temperature control instructions brings along significantly improved temperature control instructions, since there is often a change of the test timing between a test execution using non-measurement-based (on non-measured-testing-profile-based) temperature control and a test execution using measurement based (measured-testing-profile-based) temperature control. In other words, it has been found that a single-step procedure for the determination of the temperature control instructions often provides non-satisfactory results. In contrast, it has been found that even a single re-execution of the determination of a plurality of temperature control instructions on the basis a (measured) testing profile provides for significantly improved temperature control instructions (which can, in some cases, be even further improved by additional iterations).

In an embodiment, the automated test equipment is configured to obtain an updated test flow, which is based on a given test flow (e.g. an original test flow) and into which the plurality of temperature control instructions are inserted, in a first iteration. Moreover, the automated test equipment is configured to execute the updated test flow, in order to obtain an updated testing profile for use in a second iteration, and the automated test equipment is also configured to obtain a refined test flow on the basis of the updated testing profile (and possibly on the basis of the given test flow and/or the updated test flow) in a second iteration.

Using such an approach, a refined test flow, which is well-adapted to the actual circumstances, can be obtained. For example, the updated test flow, which is obtained in the first iteration, may consider the (measured) DUT temperature that is obtained by the execution of the given (e.g. original test flow). Thus, the updated test flow, which is obtained in the first iteration, already constitutes a good basis for a further improvement of the temperature control instructions in the second iteration. A test may be executed using the updated test flow obtained in the first iteration, and the updated testing profile may be obtained using a DUT temperature measurement during this test execution. Accordingly, the updated testing profile may consider an improved temperature control when compared to a temperature control during the initial test execution. Therefore, the updated testing profile allows for an effective refinement (e.g. for a determination of refined or improved temperature control instructions) in the second iteration.

In an embodiment, the automated test equipment is configured to execute an updated test flow, which is based on the given test flow and into which the plurality of temperature control instructions are inserted (and which may be obtained in a first iteration). The automated test equipment is configured to evaluate an updated testing profile indicating an evolution of a DUT temperature during an execution of the updated test flow. The automated test equipment is configured to obtain refined temperature control instructions (e.g. new temperature control instructions or a modified version of the previously determined temperature control instructions) in dependence on the updated testing profile, in order to obtain a refined test flow (e.g. a new test flow or a modified version of the previously determined updated test flow) including refined temperature control instructions.

Using such an approach, the refined test flow can be obtained in an efficient and reliable manner.

In an embodiment, the automated test equipment is configured to determine the information describing a plurality of temperature peaks using a fitting approach.

Regarding the advantages of using a fitting approach, reference is, for example, made to the below explanations. Moreover, it should be noted that the usage of a fitting approach in combination with an iterative procedure allows for an efficient and reliable determination of temperature control instructions. For example, the testing profile used in the first iteration may comprise a number of distortions since it is typically based on a relatively unreliable temperature control. Thus, the fitting approach helps to provide good temperature control instructions even in the first iteration. Moreover, usage of the fitting approach allows to have identical types of information, e.g. parameters of fitting curves, both in the first iteration and in the second iteration, which in turn facilitates the determination of the refined temperature control instructions. For example, the refinement may combine parameters of the fitting curves of the first iteration with parameters of the fitting curves in the second iteration, in order to obtain the refined temperature control instructions. However, it has been found that, in many cases, parameters of fitting curves can be combined much better (e.g. since the fitting curves used in the different iterations may be of a same curve type) than the distorted testing profiles. Thus, the usage of the fitting approach together with the usage of an iterative procedure has been found to be advantageous.

Another embodiment according to the invention creates an automated test equipment, ATE, for testing a device under test, DUT. The automated test equipment is configured to obtain a testing profile (e.g. a DUT thermal profile) indicating an evolution of a DUT temperature during an execution of a given test flow (e.g. an original test flow). The automated test equipment is further configured to (automatically) analyze the testing profile, in order to determine an information describing a plurality of (significant) temperature peaks (e.g. an information describing a peak time, and/or a peak duration, and/or a peak amplitude, and/or a fitting quality). In the context of the present application, the wording “peaks” may, for example, comprise peaks in a direction towards higher temperature and may also designate “negative” peaks in a direction towards lower temperatures. The automated test equipment is configured to (automatically) analyze the testing profile, in order to determine information describing a plurality of (significant) temperature peaks using a fitting approach (e.g. using a curved fitting). Moreover, the automated test equipment is configured to obtain a plurality of temperature control instructions (e.g. cooling instructions or heating instructions) (e.g. defining a timing of a cooling or of a heating, and optionally describing a cooling strength or heating strength) for an execution of a test flow on the basis of the information describing the plurality of temperature peaks.

This automated test equipment is based on the finding that information describing a plurality of temperature peaks may be obtained with a good reliability and also with a good accuracy using a fitting approach, wherein, for example, portions of the testing profile indicating an evolution of a DUT temperature during an execution of a given test flow are approximated by (e.g. parametrized) fitting functions. By fitting smooth parametrized fitting functions to the testing profile indicating the evolution of the DUT temperature, the key parameters of the temperature peaks can be obtained with good accuracy. For example, by using appropriate (e.g. smooth) parameterized fitting functions, key characteristics of the temperature peaks can be considered, while an impact of noise and an impact of very short temperature peaks in the testing profile can be reduced or even eliminated. Consequently, the fitting approach may bring along an effect of a smoothing and/or filtering.

Furthermore, the temperature control instructions (cooling instructions or heating instructions) may be adapted (or may be well suited) for compensating thermal peaks, a temporal evolution of which is in accordance (or at least approximately in accordance) with the respective fitting functions. Moreover, by using fitting functions, the parameters of the fitting functions may, for example, be used to determine one or more parameters of the temperature control instructions (wherein, for example, a timing of the temperature control instructions may be determined by a timing of the fitting functions, and wherein, for example, a cooling intensity or heating intensity defined by the temperature control instructions may, for example, be determined by amplitudes of the (parametrized) fitting functions). Moreover, by using the fitting approach, a number of temperature control instructions can be kept comparatively small, since temperature control instructions may primarily be provided for such thermal events (e.g. thermal peaks or temperature peaks) that can be well-fitted by a fitting function, such that, for example, an excessive number of temperature control instructions can be avoided.

Moreover, it has been recognized that the fitting approach is, in many cases, better suited for determining appropriate temperature control instructions when compared to other approaches, since the fitting approach effectively “converts” thermal events of arbitrary shape (e.g. of arbitrary temporal evolution) into “standardized” fitting curves for which appropriate temperature control instruction can be easily derived.

To conclude, it has been found that the determination of the temperature control instructions using the fitting approach for the determination of information describing a plurality of temperature peaks brings along a good comprise between an accuracy of the temperature control and an implementation effort. Moreover, in some cases, the fitting approach allows for a fully automatic determination of the temperature control instructions on the basis of the testing profile, and is also well suited for a determination of temperature control instructions which involves some human interaction (wherein the fitting approach typically significantly supports a human user since the fitting approach supports an identification of thermal events and also a determination for appropriate temperature control instructions and temperature control parameters).

In an embodiment, any of the automated test equipment disclosed herein may be configured to fit respective fitting functions (e.g. parabolic fitting functions defined by one or more respective parameters, or Gaussian fitting functions defined by one or more respective parameters, or normal distribution fitting functions defined by one or more respective parameters, or other fitting functions, such as Lorentzian or Voigt functions) to a plurality of thermal peaks within the testing profile, in order to obtain parameters of the thermal peaks (e.g. parameters describing a respective timing of the thermal peaks and/or parameters describing heights or intensities of the thermal peaks). For example, the parameters of the thermal peaks may constitute the information describing the plurality of temperature peaks.

It has been found that a fitting of such respective fitting functions to a plurality of thermal peaks within the testing profile allows for a computationally efficient and well-defined derivation of parameters of the thermal peaks. Well known and efficiently implementable curve fitting algorithms can be applied, such that a computational effort remains reasonably small. Furthermore, by using a well-defined fitting function, the parameters of the thermal peaks can be determined in such a manner that the temperature control instructions (which may also comprise one or more parameters, like a time parameter and/or an intensity parameter) can be easily derived from the parameters of the thermal peaks. In particular, the fitting functions can be chosen such that they well correspond to a cooling profile (or heating profile) that is obtainable by an execution of the temperature control instructions.

In an embodiment, any of the automated test equipment disclosed herein may be configured to determine the one or more temperature control instructions (e.g. cooling instructions or heating instructions) in dependence on one or more parameters of the one or more fitting functions. Accordingly, the parameters of the cooling instructions or heating instructions can be determined in a very efficient manner, wherein the curve fitting contributes to eliminate noise and to have parameters of the heating functions or cooling functions that are adapted to an evolution of a testing profile over a certain temporal extension (e.g. over a temporal extension that is of the order of the temporal extension of a fitting function). Consequently, by determining the one or more temperature control instructions (or, more precisely, the parameters of the one or more temperature control instructions) on the basis of the fitting approach, the temperature control instructions can be well adapted to an actual evaluation of the testing profile over a significant temporal portion, e.g. without being significantly affected by thermal noise.

In an embodiment, any of the automated test equipment disclosed herein may be configured to identify a plurality of temperature peaks in the testing profile using a temperature threshold value (which may, for example, be determined automatically or which may, for example, be set by a user) and/or in dependence on an extension (e.g. in dependence on an area; e.g. in dependence on an area of a time-temperature integral; e.g. in dependence on an area above a temperature threshold value) of respective temperature peaks. Moreover, the automated test equipment is configured to fit respective fitting functions (e.g. parabolic fitting functions defined by one or more respective parameters, or Gaussian fitting functions defined by one or more respective parameters, or other fitting functions, e.g., as mentioned above) to the identified temperature peaks, or to a subset of the identified temperature peaks, in order to obtain the information describing the thermal peaks.

Using such an approach, in which a plurality of temperature peaks (also designated as thermal peaks) are identified using a first (typically more computationally efficient) criterion, and in which a curve fitting approach (which is typically computationally more demanding than the mere identification of the thermal peaks) is applied in a second step, a high overall computational efficiency can be achieved. Also, it can be avoided that relatively small thermal peaks, which do not fulfill the identification criterion (e.g., which do not exceed a temperature threshold value or which only comprise a small extension) are fitted, wherein such a fitting would involve comparatively high computational effort (higher than a computational effort for a mere threshold decision) and would foreseeably result in an unnecessary temperature control instruction. Accordingly, the two-step concept to first identify a plurality of temperature peaks in a testing profile using a first criterion and to then apply the curve fitting approach (only) to the identified temperature peaks, or to a subset of the identified temperature peaks, provides a particularly good computational efficiency and at the same time provides meaningful temperature control instructions.

In an embodiment, any of the automated test equipment disclosed herein may be configured to filter out (e.g., exclude) or to neglect thermal events (e.g., thermal peaks or temperature peaks) having a comparatively smaller relevance (e.g., thermal events having a smaller likelihood to be relevant; e.g., thermal events having a smaller likelihood to affect a functionality of a device under test) (e.g., using one or more smart filters, parameters of which are adjusted automatically and/or independence on a user interaction) and to obtain the temperature control instructions on the basis of thermal events (e.g., thermal peaks) having a comparatively higher relevance (e.g., having a comparatively higher likelihood to be relevant; e.g., thermal events having a comparatively higher likelihood to affect a functionality of the device under test).

By selectively filtering out or neglecting thermal events having a comparatively smaller relevance, a number of temperature-control instructions can be kept reasonably small, which may be helpful or even needed in some testing environments. Also, a computational effort for determining the temperature control instructions can be kept reasonably small using such a preprocessing (e.g., using a filtering out of thermal events having comparatively smaller relevance).

Moreover, it can be avoided that a test program is overloaded with an excessive number of temperature control instructions. Furthermore, noise-like distortions within the testing profile can be addressed and eliminated using such an approach.

In an embodiment, any of the automated test equipment disclosed herein may be configured to classify thermal events (e.g., thermal peaks or temperature peaks) as thermal events having a small (or comparatively smaller) significance (e.g., thermal events having a smaller likelihood to be relevant; e.g., thermal events having a smaller likelihood to affect a functionality of a device under test) (e.g., using one or more smart filters, parameters of which are adjusted automatically and/or independence on a user interaction) and to (or as) thermal events (e.g., thermal peaks or temperature peaks) having a high (e.g., comparatively higher) significance (e.g., having a comparatively higher likelihood to be relevant; e.g., thermal events having a comparatively higher likelihood to affect a functionality of the device under test). Moreover, the automated test equipment is configured to obtain the temperature control instructions on the basis of the thermal events having (e.g., classified as having) the high significance (while leaving thermal events classified as having a low significance unconsidered). By using such a classification of the thermal events into, for example, two classes (e.g., thermal events having a small significance and thermal events having a higher significance), a number of temperature control instructions can be kept reasonably small, which results in a good computational efficiency and also in a good efficiency of the test program.

In an embodiment, any of the automated test equipment disclosed herein may be configured to take into account a minimum overheating event duration threshold value when determining the information describing the plurality of (significant) temperature peaks. Accordingly, the automated test equipment can, for example, avoid a provision of a temperature control instruction in the case of a very short overheat event, which can be expected to have little impact on a result of the test. Consequently, “spikes” in the testing profile can be suppressed, which increases the reliability of the generation of the temperature control instructions and keeps the number of temperature control events reasonably small.

In an embodiment, any of the automated test equipment disclosed herein may be configured to fit a common fitting function (e.g., a parabolic fitting function defined by one or more parameters, or a Gaussian fitting function defined by one or more parameters, or another fitting function, e.g., as mentioned above) to two or more adjacent thermal peaks (e.g. temperature peaks) within the testing profile.

Using such an approach, a common temperature control instruction can be generated for two or even more adjacent thermal peaks within the testing profile, which keeps the number of temperature control instructions reasonably small. When using such an approach, it can be exploited that a single temperature control instruction is well suited for usage in situations in which two or more thermal peaks are closely adjacent. In particular, the fact that a common fitting function can be well fitted (e.g. with a relatively small fitting error) to two or more adjacent thermal peaks within the testing profile can be used as a reliable indication that a single temperature control information is well suited for an active temperature control in such a situation. On the other hand, if the automated test equipment recognizes that the fitting of a common fitting function to two or more thermal peaks within the testing profile would result in an excessive fitting error (e.g., exceeding a predetermined threshold value), the automated test equipment may conclude that separate fitting functions should be fitted to the different thermal peaks, and the automated test equipment may also conclude, in such a situation, that a single temperature control instruction may not be sufficient for a reliable active temperature control.

In an embodiment, any of the automated test equipment disclosed herein may be configured to evaluate a maximum overheating event proximity parameter (which may, for example, be set by a user or which may, for example, be set automatically) to decide whether a common fitting function should be fitted to two or more adjacent thermal peaks in a testing profile.

Using such a maximum overheat event proximity parameter, the automated test equipment may therefore efficiently decide whether a common fitting function may be appropriate to fit two or more adjacent peaks. Thus, by evaluating the maximum overheat event proximity parameter, a good computational efficiency may be reached, since the determination of the maximum overheat event proximity parameter (which may, for example, describe a temporal distance between two adjacent thermal peaks within the testing profile) is typically computationally less demanding than a fitting approach (that may be unsuccessful if the temporal distance between two adjacent thermal peaks is too large). Thus, the automated test equipment may use an efficient concept to pre-classify for which of the thermal peaks within the testing profile a common fitting (using a common fitting function) appears to be promising.

In an embodiment, any of the automated test equipment disclosed herein may be configured to obtain a combined temperature control event or a combined temperature control instruction (e.g., a combined cooling event or a combined cooling instruction or a combined heating event or a combined heating instruction) on the basis of two or more (e.g., adjacent) fitted temperature peaks (e.g., on the basis of two or more fitted temperature peaks which overlap temporally, or on the basis of two or more fitted temperature peaks having a distance smaller than a threshold distance).

By providing a combined temperature control event or a combined temperature control instruction on the basis of two or more adjacent fitted temperature peaks, the number of temperature control instructions can be kept reasonably small which facilitates the execution of the temperature control instructions by the automated test equipment. Moreover, in some circumstances, a more smooth evaluation of the temperature at the device under test can be achieved using such an approach.

In an embodiment, any of the automated test equipment disclosed herein may be configured to automatically adjust a criterion (e.g., a temporal criterion; e.g., a maximum overheat event proximity parameter) for obtaining a combined temperature control event or a combined temperature control instruction (e.g., a combined cooling event or a combined cooling instruction or a combined heating event or a combined heating instruction) on the basis of two or more (e.g., adjacent) fitted temperature peaks, such that a total number of temperature control events (e.g., cooling events or heating events) or a total number of temperature control instructions (e.g., cooling instructions or heating instructions) does not exceed a predetermined maximum value.

Using such an approach, the automated test equipment may automatically make a best usage of the active temperature control resources, in particular, in a case in which the temperature control resources only allow a maximum total number of temperature control instructions. By automatically adjusting the criterion for obtaining a combined temperature control event or a combined temperature control instruction, the automated test equipment may adjust the criterion in such a manner that a best possible active temperature control can be achieved, even though the “combined” temperature control instructions may not provide ideal temperature control for the individual temperature peaks. However, by varying (or adjusting) the criterion for obtaining a combined temperature control instruction, the automated test equipment can vary (e.g. optimize) the value of said criterion to achieve a situation in which all significant thermal peaks (or temperature peaks) are “covered” (at least in a sub-optimal but sufficient manner) by temperature control instructions while avoiding to exceed a maximum allowable number of temperature control instructions. Thus, a “best possible” active temperature control result can be obtained (e.g., automatically, without a high degree of user interaction).

In an embodiment, any of the automated test equipment disclosed herein may be configured to select a limited number of thermal peaks in (e.g. determined by a user setting), out of an overall number of thermal peaks within a testing profile, for a determination of the information describing a plurality of (significant) temperature peaks or for obtaining the plurality of temperature control instructions.

By selecting a limited number of thermal peaks, the computational effort can be kept reasonably small, and a number of temperature control instructions can also be kept so small that they can be well-handled by the hardware equipment. Furthermore, a pre-selection of a limited number of thermal peaks, (for example on the basis of simple criterion, an evaluation of which needs less computational resources than the fitting approach) can help to save computational resources and can therefore also bring an improved usability (e.g. in a system in which user settings and the result of these user settings are visualized in close-to-real-time).

In an embodiment, any of the automated test equipment disclosed herein may be configured to correlate a timing information of the information describing a plurality of temperature peaks with test flow events (e.g. with calls of subroutines of a test flow) (e.g. by identifying test flow events that are in a temporal proximity to desired cooling start points derived from the information describing a plurality of temperature peaks).

By using such an approach, it is possible to reliably determine a timing of the temperature control instructions. For example, by determining a correlation between a timing information of the information describing a plurality of temperature peaks and a timing of test flow events, the temperature control instructions can be tied to, or linked with, test flow events. Accordingly, it can, for example, be determined that a temperature control instruction is inserted into the test flow in close temporal proximity (e.g. directly before or directly after) to a test flow event that has been identified by the correlation, or a predetermined time before a test flow event that has been identified by the correlation. Consequently, it can be achieved that the temperature control instruction is executed at an appropriate time (or at an appropriate position, e.g. within an order of test flow instructions) during an execution of the test flow, such that the temperature control information can have a best possible effect.

In an embodiment, any of the automated test equipment disclosed herein may be configured to receive an input test flow and to insert the plurality of cooling instructions (e.g. pre-trigger cooling signals for problematic test suites causing over-heat) into the input test flow (e.g. before tests or “test suites” that have been identified to cause over-heat), to obtain an updated test flow. Moreover, the automated test equipment is configured to insert the temperature control instructions into the input test flow to start the temperature control (e.g. a cooling or a heating) before a beginning of a temperature peak (e.g. on the basis of the information describing the plurality of temperature peaks).

By using such an approach, the test flow can be used to control both an execution of tests or “test suites” and the active thermal control. Thus, the input test flow may be supplemented by temperature control instructions, wherein said temperature control instructions may, for example, be inserted at appropriate positions within the input test flow. For example, by placing a temperature control instruction shortly before a command to execute a certain test or test suite that has been found to cause a temperature peak, a cooling may be pre-triggered shortly before this test or test suite is started. Thus, by inserting the temperature control instructions into the test flow, a very good temporal synchronization between the execution of the test flow (comprising tests or test suites) and the active temperature control can be achieved. By having temperature control instructions inserted into the test flow, this synchronization between the execution of the test flow and the active temperature control can even be reached in case that different tests or test suites are not time-deterministic. Thus, a very good temperature control can be achieved during the execution of the test flow, wherein the generation of a test flow comprising both instructions to perform tests or test suites and temperature control instructions allows for a particularly simple control of an overall test.

In an embodiment, any of the automated test equipment disclosed herein may be configured to obtain (e.g. receive or generate) a test log file (e.g. an EDL file; e.g. a log file describing a timing of an execution of test functions of a test flow; e.g. a file indicating how long test steps of a test flow were run) which is associated with the thermal profile (e.g. which belongs to a same test execution as the thermal profile). Moreover, the automated test equipment is configured to insert the temperature control instructions into the test flow using information of the test log file (e.g. taking into consideration which test or test suite or test function of test flow has been started in a temporal proximity before a thermal peak, and tying a temperature control instruction to said test or test suite or test function (or to a call starting said test function) that has been started in the temporal proximity before the thermal peak).

Using a test log file, the automated test equipment can determine in which position within a test flow a temperature peak has occurred. For example, the thermal profile may describe the temporal evolution of the temperature, and the test log file may describe at which time (e.g. measured in real time) the different tests or test suites have actually been started and/or have been completed. This may, for example, be in contrast with the test flow, wherein the test flow may, for example, not describe a detailed (real physical time) timing of the execution of the tests or test suites (e.g. because the test or test suites may be non-time-deterministic). In other words, the automated test equipment may use the test log file to conclude from the times of the temperature peaks (e.g. indicated in real physical time) to the specific tests or test suites of a test flow, and may therefore conclude at which position within a test flow (e.g. before the start of a test or test suite that causes temperature peak) a temperature control instruction should be inserted. Thus, by jointly using the test profile and the test log file, the automated test equipment may insert the temperature control instructions into the test flow at appropriate positions.

In an embodiment, any of the automated test equipment disclosed herein may be configured to jointly visualize the testing profile (e.g. a DUT thermal profile) indicating an evolution of a DUT temperature during an execution of a given test flow, and respective fitting functions (e.g. parabolic fitting functions defined by one or more respective parameters, or Gaussian fitting functions defined by one or more respective parameters, or other fitting functions, e.g. as described herein) fitted to a plurality of thermal peaks within the testing profile.

With such a joint visualization, it is possible for a user of the automated test equipment to efficiently check whether the fitting has been performed in a reliable manner. Moreover, it is also possible for a user of the automated test equipment to change one or more parameters of the fitting approach, and/or one or more further parameters for the analysis and/or processing of the testing profiles, and to see resulting fitting functions in a quasi-instantaneous (e.g. quasi-real-time) manner. Accordingly, the user of the automated test equipment can efficiently adjust parameters for the extraction of the temperature control instructions while having a good insight into the effect of parameter variations. Thus, the user of the automated test equipment can set the parameters in a well-informed manner.

In an embodiment, any of the automatic test equipment disclosed herein may be configured to also visualize temperature control periods (e.g., cooling periods or heating periods) determined using the information describing a plurality of (significant) temperature peaks (e.g., within the joint visualization of the testing profile and the respective fitting curves).

Consequently, the user of the automated test equipment provides an excellent overview over the functionality of the automated test equipment. In particular, by also visualizing the temperature control periods determined using the information describing a plurality of (significant) temperature peaks, the user of the automated test equipment can obtain an insight how the temperature control periods correlate with the identified temperature peaks, and the user of the automated test equipment can also obtain an insight how parameter variations (e.g., manual parameter variations) affect the actual temperature control periods (e.g., cooling periods or heating periods) that are automatically derived by the automated test equipment (e.g., using the manually adjusted parameters). Thus, a user gets significant support in choosing appropriate parameters, since he can quickly recognize the temperature control periods (which are typically controlled by the temperature control instructions) that result from these settings. Accordingly, the automated test equipment is particularly user friendly.

In an embodiment, any of the automated test equipment disclosed herein may be configured to update (e.g., in real time or quasi-real-time) the visualization in response to a user interaction changing one or more parameters (e.g., a temperature threshold and/or a minimum overheat event duration threshold value, and/or any other user selected parameter).

Thus, the user gets quick visual feedback to his user interaction, which typically helps the user to choose appropriate parameters for the determination of the one or more temperature control instructions. This allows the user to obtain good, or even approximately optimal, settings of the automated test equipment, which results in temperature control instructions that are well-suited for a specific test task. In particular, the experience of the user can be utilized, while the determination of the temperature control instructions is still significantly supported by the automated test equipment. Consequently, a good active temperature control result can be obtained that allows usage of the experience of the user of the automated test equipment and provides a uniformity of the automatic determination of the temperature control instructions.

In an embodiment, any of the automated test equipment disclosed herein may be configured to iteratively obtain (e.g., determine) the temperature control instructions.

By iteratively determining the temperature control instructions, it is possible to refine the temperature control instructions which have been obtained in a previous processing. For example, a first set of temperature control instructions (also designated as initial set of temperature control instructions) can be obtained on the basis of a testing profile (“initial testing profile”), which has been obtained without any cooling, or which has been obtained using a constant cooling, or which has been obtained using a manually defined cooling profile. Thus, the “first” testing profile (or “initial testing profile”) may represent an evolution of the temperature of the device under test, which is obtained without the usage of an active temperature control. Accordingly, initial temperature control instructions can be derived on the basis of this “first” or “initial” testing profile.

Subsequently, a test can be run, wherein in this test run, the initial temperature control instructions generated on the basis of the initial testing profile may be applied, and an updated testing profile may be obtained. In the updated testing profile, typically some of the temperature peaks that have been present in the initial testing profile may be significantly reduced, or even eliminated, due to the execution of the temperature control instructions.

However, remaining temperature peaks may be evaluated to refine the temperature control instructions, for example, by changing one or more parameters of the temperature control instructions and/or by replacing one temperature control instruction (e.g. out of the initial temperature control instructions) by another temperature control instruction. Moreover, additional temperature control instructions could also be added on the basis of the updated testing profile. Accordingly, the quality of the temperature control can be improved iteratively, wherein, for example, a degradation of the test, which may be caused by the lack of an adaptive temperature control during the execution of the initial test may be overcome by the improved test (using the first initial set of temperature control instructions). Consequently, the testing may, for example, step-wisely approximate ideal conditions.

Moreover, it has been found that the iterative approach significantly outperforms simulation approaches, since it is typically very difficult to precisely simulate a thermal behavior of a device under test during a test flow.

Moreover, it has been found that the iterative approach results in reliable (step-wisely improved) temperature control instructions, since it has been recognized that the initial execution of a test flow (without active temperature control) typically deviates significantly (e.g., with respect to a timing) from a subsequent test execution, e.g. executed using the initial temperature control instructions.

To conclude, it has been found that the iterative obtention of the temperature control instructions using multiple executions of a test flow, wherein temperature control instructions (or, more precisely, parameters of the temperature control instructions) are iteratively improved in multiple passes, results in highly reliable temperature control instructions.

In an embodiment, any of the automated test equipment disclosed herein may be configured to execute an updated test flow, which is based on the given test flow and into which the plurality of temperature control instructions (e.g. first temperature control instructions or initial temperature control instructions) (which are obtained on the basis of the information describing a plurality of temperature peaks) (and which are determined, for example, on the basis of the initial testing profile) are inserted. In this case, the automated test equipment is configured to evaluate an updated testing profile (e.g., DUT thermal profile) indicating an evolution of a DUT temperature during an execution of the updated test flow. Furthermore, the automated test equipment is configured to refine the temperature control instructions in dependence on the updated testing profile, in order to obtain a refined test flow including a refined temperature control instructions (e.g., refined temperature control instructions having refined timing and/or refined intensity when compared to the (original/previous) temperature control instructions included in the updated test flow).

Using such an approach, highly reliable temperature control instructions can be obtained, even though the initial test flow (which has resulted in the initial testing profile) may have been executed without using active temperature control (or with only a very unreliable active temperature control that is not based on actual measurements). For example, changes in DUT timing between the execution of the initial test flow and the execution of the updated test flow may be taken into account by the evaluation of the updated testing profile which indicates the evolution of DUT temperatures during execution of the updated test flow. Thus, the refined temperature control instructions, which are obtained on the basis of the updated testing profile, may be significantly better adapted to an actual DUT behavior under the condition of a temperature control than the initially obtained temperature control instructions.

Thus, a highly reliable test result can be obtained by using the refined test control instructions, rather than the initially obtained test control instructions.

An embodiment according to the present invention creates a method for testing a device under test, DUT. The method comprises obtaining a testing profile (e.g., a DUT thermal profile) indicating an evolution of a DUT temperature during an execution of a given test flow. The method comprises (e.g., automatically) analyzing the testing profile, in order to determine an information describing a plurality of (significant) temperature peaks (e.g., an information describing a peak time, and/or a peak duration, and/or a peak amplitude, and/or a fitting quality) using a fitting approach (e.g., a curve fitting). For example, peaks may comprise peaks in a direction towards higher temperatures and/or peaks in a direction towards lower temperatures.

Moreover, the method comprises obtaining a plurality of temperature control instructions (e.g., cooling instructions or heating instructions) (e.g., defining a timing of a cooling or of a heating, and optionally describing a cooling strength or heating strength) for an execution of a test flow on the basis of the information describing the plurality of temperature peaks.

This method is based on the same considerations like the above-described automated test equipment. Moreover, it should be noted that the method may also be supplemented by any of the features, functionalities and the details disclosed herein, also with respect to the automated test equipment.

Another embodiment according to the invention creates a computer program for performing the method when the computer program runs on a computer. The computer program is based on the same considerations like the above-described automated test equipment and the above-described method.

### BRIEF DESCRIPTION OF THE DRAWINGS

Embodiments of the present invention will be detailed subsequently referring to the appended drawings, in which:

FIG. 1 shows a block schematic diagram of an automated test equipment, according to an embodiment of the present invention;

FIG. 2 shows a block schematic diagram of an automated test equipment, according to another embodiment of the present invention;

FIG. 3 shows a block schematic diagram of an automated test equipment, according to another embodiment of the present invention;

FIG. 4 shows a graphic representation of a reduction of a temperature;

FIG. 5 shows a graphic representation of an updated test flow, which can be provided by embodiments according to the present invention;

FIG. 6 shows a graphic representation of a work flow model chart, according to an embodiment of the invention;

FIG. 7 shows a graphic representation of a software structure, according to an embodiment of the invention;

FIG. 8 shows a graphic representation of a user interface, according to an embodiment of the present invention;

FIG. 9 shows a graphic representation of a DUT temperature profile and of heating functions fitted to the DUT temperature profile;

FIG. 10a shows a graphic representation of a user interface, according to an embodiment of the present invention;

FIG. 10b shows a graphic representation of a thermal profile, of heating functions fitted to the thermal profile, and of temperature control time intervals;

FIG. 11 shows a graphic representation of data provided by an embodiment of the present invention;

FIG. 12 shows a flow chart of a method, according to an embodiment of the present invention;

FIG. 13 shows a flow chart of a method, according to an embodiment of the present invention; and

FIG. 14 shows a graphic representation of a user interface, which can be used in embodiments of the invention; and

FIG. 15 shows a graphic representation of an automation window, which can be used in embodiments of the invention.

### DETAILED DESCRIPTION OF THE INVENTION

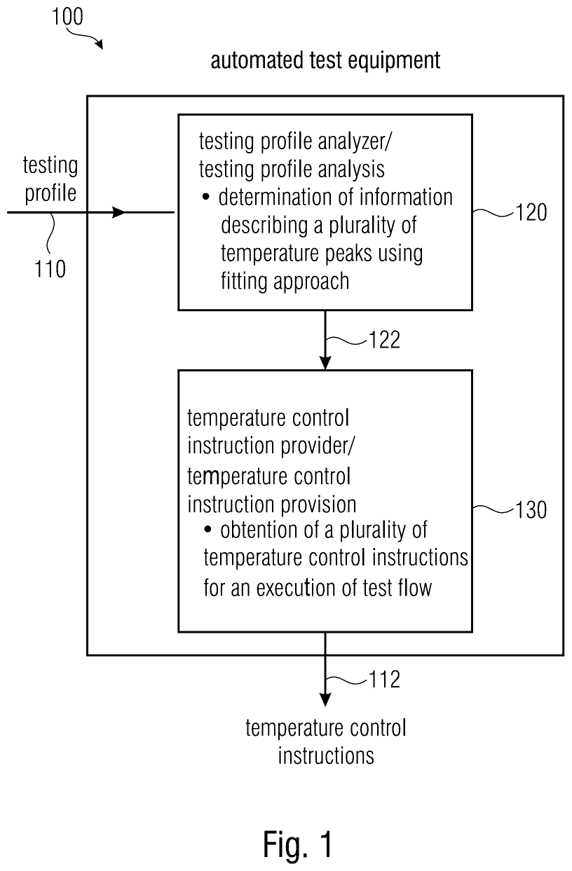

### Automated Test Equipment According to FIG. 1

FIG. 1 shows a schematic representation of an automated test equipment, according to an embodiment of the present invention.

Automated test equipment, ATE, 100 serves for testing a device under test. For example, the automated test equipment 100 provides stimulus signals to a device under test and evaluates response signals provided by the device under test in response to the stimulus signals. However, the automated test equipment may alternatively be adapted to perform a system-on-the-chip test, which may, for example, comprise uploading a test software onto a device under test and evaluating signals or data provided by the device under test. For example, the test may be performed under the control of a test program or a test flow.

The automated test equipment 100 is configured to obtain a testing profile 110 (e.g., a DUT thermal profile) indicating an evolution of a DUT temperature during an execution of a given test flow. Moreover, the automated test equipment 100 provides a plurality of temperature control instructions 112. The temperature control instructions 112 may, for example, be cooling instructions and/or heating instructions. For example, the temperature control instructions may define a timing of a cooling or a timing of a heating. Optionally, the temperature control instructions also describe a cooling strength or a heating strength. The temperature control instructions 112 may, for example, be obtained for an execution of a test flow (wherein, for example, the temperature control instructions may be inserted into a test flow).

The automated test equipment 100 comprises a testing profile analyzer or a testing profile analysis 120 which is configured to analyze (e.g., automatically analyze) the testing profile 110, in order to determine an information 122 describing a plurality of temperature peaks (e.g., a plurality of significant temperature peaks) using a fitting approach (e.g., a curve fitting). The information 122 describing a plurality of (e.g., significant) temperature peaks may, for example, be, or comprise, an information describing a peak time, and/or a peak duration, and/or a peak amplitude, and/or a fitting quality. However, it should be noted that peaks may, for example, comprise peaks in a direction towards higher temperature and/or peaks in a direction towards lower temperatures. Moreover, the automated test equipment 100 comprises a temperature control instruction provider/temperature control instruction provision 130 that is configured to obtain a plurality of temperature control instructions, e.g., cooling instructions or heating instructions 112, for an execution of a test flow on the basis of the information 122 describing a plurality of temperature peaks.

To conclude, the automated test equipment 100 may provide the temperature control instructions 112 on the basis of the testing profile 110, wherein a fitting approach (e.g., a curve fitting approach) may be used by the testing profile analyzer/testing profile analysis 120 to determine the information 122 describing a plurality of temperature peaks, and wherein the temperature control instruction provider/temperature control instruction provision 130 may use the information 122 to provide the temperature control instructions 112. The temperature control instructions 112 may then, for example, be inserted into a test flow (or into a test program defining the test flow).

However, it should be noted that the automated test equipment 100 according to FIG. 1 may optionally be supplemented by any of the features, functionalities or details disclosed herein, both individually and taken in combination.

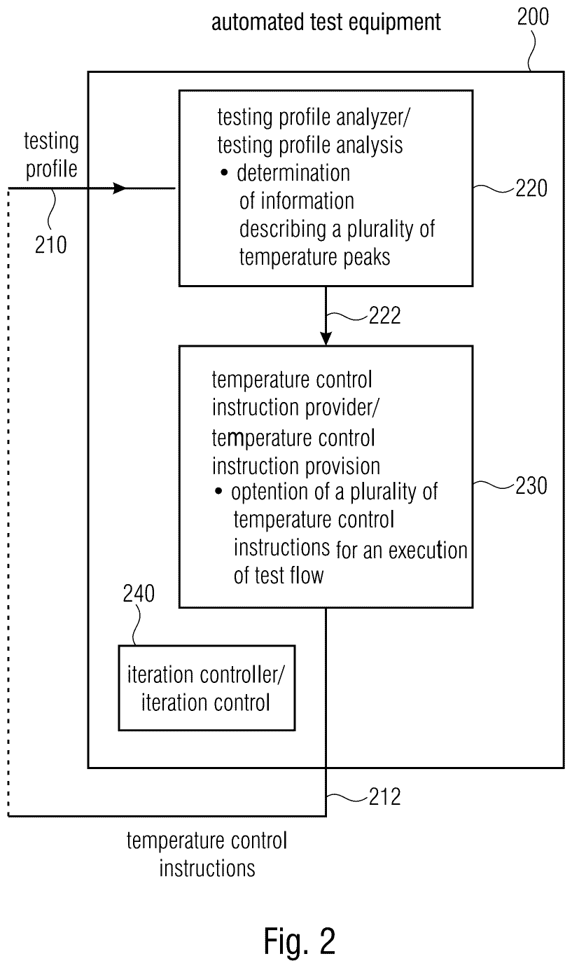

### Automated Test Equipment According to FIG. 2

FIG. 2 shows a block schematic diagram of an automated test equipment, according to another embodiment of the present invention. The automated test equipment 200 is configured to obtain (e.g., receive) a testing profile (e.g., a DUT thermal profile) indicating an evolution of a DUT temperature during an execution of a given test flow. The testing profile 210 may, for example, correspond to the testing profile 110.

The automated test equipment 200 is configured to provide a plurality of temperature control instructions 212, wherein the temperature control instructions 212 may, for example, be cooling instructions and/or heating instructions. For example, the temperature control instructions 212 may define a timing of a cooling or a timing of a heating. Moreover, the temperature control instructions 212 may optionally describe a cooling strength or a heating strength. Accordingly, the automated test equipment 200 may be configured to obtain the plurality of temperature control instructions 212 for the execution of a test flow.

The automated test equipment 200 comprises a testing profile analyzer/testing profile analysis 220, wherein the testing profile analyzer/testing profile analysis 220 is configured to analyze (e.g., automatically analyze) the testing profile 210, in order to determine an information 222 describing a plurality of temperature peaks (e.g., a plurality of significant temperature peaks). For example, the information describing a plurality of temperature peaks may be an information describing a peak time, and/or a peak duration, and/or a peak amplitude, and/or a fitting quality. In this regard, peaks may, for example, comprise peaks in a direction towards higher temperatures and/or peaks in a direction towards lower temperatures. For example, but not necessarily, the testing profile analyzer 220 may be configured to analyze the testing profile, in order to determine the information describing a plurality of temperature peaks using a fitting approach (e.g., a curve fitting). However, it should be noted that different approaches for determining the information 222 describing a plurality of temperature peaks may also be applied.

The automated test equipment 200 also comprises a temperature control instruction provider/temperature control instruction provision 230, wherein the temperature control instruction provider/temperature control instruction provision may be configured to obtain the plurality of temperature control instructions 212 for an execution of a test flow. For example, the temperature control instruction provider/temperature control instruction provision 230 may be configured to obtain cooling instructions or heating instructions which may, for example, define a timing of a cooling and/or of a heating and which may optionally describe a cooling strength and/or a heating strength.

For example, the temperature control instructions 212 may be included into a test flow or, for example, into a test program defining a test flow.

Moreover, the automated test equipment 200 comprises an iteration controller/iteration control 240, wherein the iteration controller/iteration control 240 may be configured to control an iterative obtention (e.g., determination) of the temperature control instructions 212. For example, the iteration controller 240 may be configured to control the automated test equipment 200 in such a manner that initial temperature control instructions are obtained on the basis of an original testing profile 210, wherein, for example, the original testing profile may be obtained without an active temperature control. The original testing profile may, for example, be obtained using an original (initial) test flow in which there are no temperature control instructions or in which there are no temperature control instructions varying the cooling or heating multiple times during the execution of the test flow. The initial temperature control instructions may be obtained by the automated test equipment 200 on the basis of such an original (initial or first) testing profile, and the initial (original or first) temperature control instructions may then be inserted into a test flow, to obtain an updated test flow.

The iteration controller 214 may then control the automated test equipment to run the updated test flow and to obtain an updated testing profile (which may, for example, describe the DUT temperature during the execution of the updated test flow). The updated testing profile 210 may then be used by the automated test equipment to obtain refined temperature control instructions. For example, parameters of the initial temperature control instructions may be modified in order to obtain the refined temperature control instructions. For example, the updated testing profile may indicate (e.g. represent) an evolution of the DUT temperature in the presence of a test flow which considers the initial (first) temperature control instructions. However, due to imperfections of the initial temperature control instructions, the updated testing profile may still exhibit one or more temperature peaks. Consequently, the automated test equipment 200 may, for example, under the control of the iteration controller, obtain revised (e.g. refined) temperature control instructions that are intended to counteract temperature peaks within the updated testing profile. Consequently, revised (e.g. refined) temperature control instructions are obtained, which may be inserted to obtain a revised (e.g. refined) test flow. One or more additional iterations may optionally be performed under the control of the iteration controller 240, to thereby further improve the temperature control instructions (or the parameters of the temperature control instructions).

Thus, the automated test equipment is configured to use one or more iterations in order to obtain improved (e.g., revised or refined) temperature control instructions which are typically better adapted to the actual testing procedure than initial temperature control instructions that are obtained on the basis an original (first, initial) testing profile. During the iterations, the test flow may be modified by using a new (e.g., revised) set of one or more temperature control instructions after each iteration.

Consequently, such an iterative approach may, for example, address the fact that a timing of an execution of a test flow may change in the presence of an active temperature control. Thus, since the timing of the execution of the test flow may change in the presence of an active temperature control, it is apparent that the original (first, initial) testing profile is associated with a test timing that deviates from a test timing (e.g. test flow timing) that is obtained by using the initial temperature control instructions. Accordingly, the initial temperature control instructions, or a test flow that is based on the initial temperature control instructions, may sometimes not provide a sufficient accuracy. However, the accuracy of the temperature control instructions may be improved significantly by performing one or more iterations, since the updated testing profile is typically already obtained under much more appropriate thermal conditions than the original testing profile. Consequently, the updated testing profile allows for the obtention of revised (e.g. refined) temperature control instructions, wherein said revised (e.g. refined) temperature control instructions typically lead to an improved active temperature control when compared to the initial temperature control instructions. Optionally, further iterations may bring along additional improvements. Accordingly, a very high quality of the temperature control instructions can be obtained.

However, it should be noted that the automated test equipment 200 according to FIG. 2 may optionally be supplemented by any of the features, functionalities and details described herein, both individually and taken in combination.

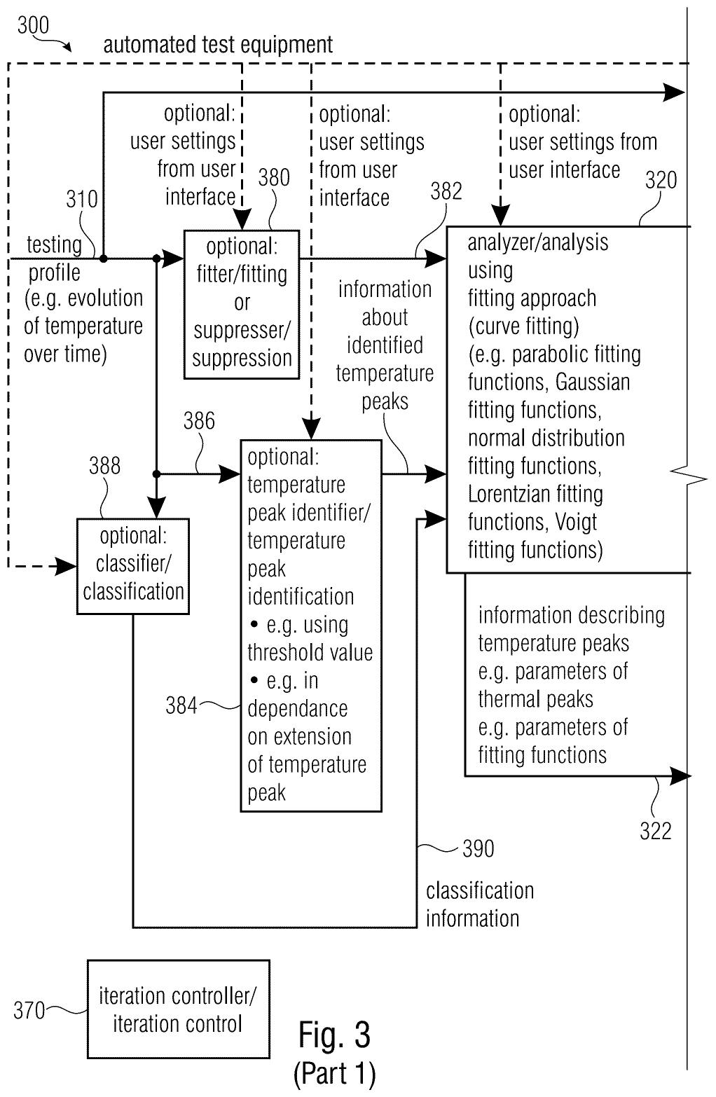

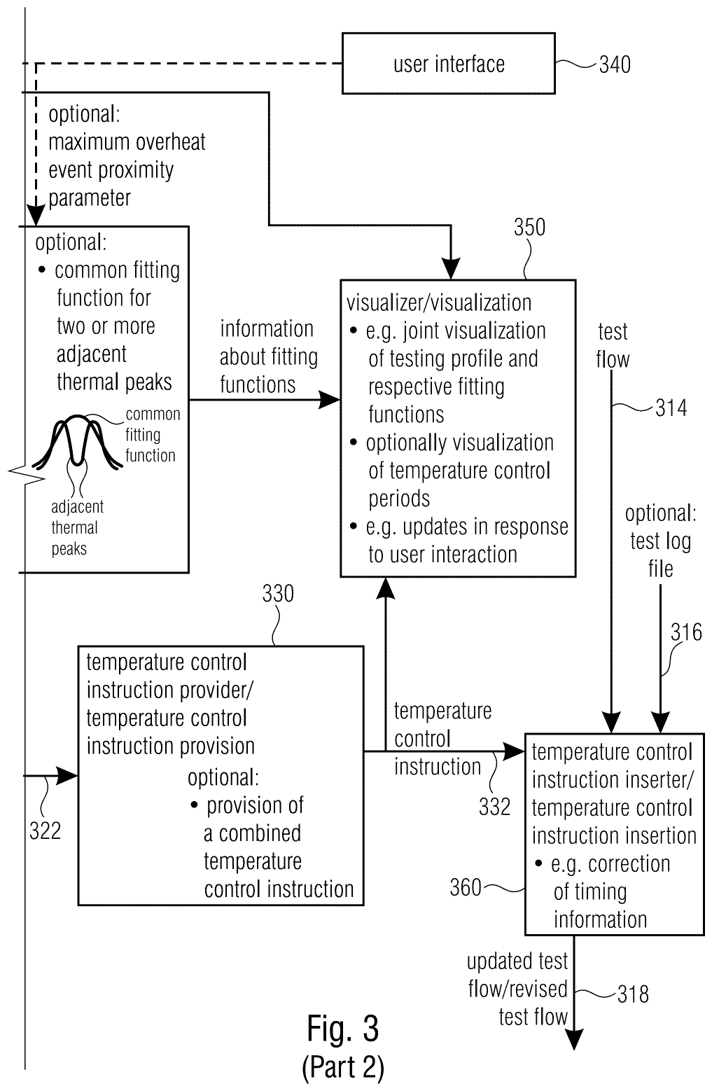

### Automated Test Equipment According to FIG. 3

FIG. 3 shows a block schematic diagram of an automated test equipment, according to an embodiment of the present invention. The automated test equipment 300 according to FIG. 3 is configured to obtain a testing profile 310, which may describe an evolution of a temperature over time. The automated test equipment 300 may further be configured to obtain (e.g., receive or generate) a test flow 314 (e.g. from a test design software), and the automated test equipment 300 may optionally be configured to receive a test log file 316. The automated test equipment then provides, on the basis thereof, an updated test flow or a revised test flow (e.g. a refined test flow) 318.

The automated test equipment 300 comprises, as important components, an analyzer/analysis 320 (which may, for example, correspond to the testing profile analyzer 120 or to the testing profile analyzer 220), a temperature control instruction provider/temperature control instruction provision 230, which may, for example, correspond to the temperature control instruction provider/temperature control instruction provision 130 or to the temperature control instruction provider/temperature control instruction provision 230, a user interface 340 and a visualizer/visualization 350. Moreover, the automated test equipment comprises, a temperature control instruction inserter/temperature control instruction insertion 360. Moreover, the automated test equipment 300 also comprises an iteration controller/iteration control 370 which may, for example, correspond to the iteration controller/iteration control 240. However, it should be noted that, in some embodiments, the user interface 340, and/or the visualizer/visualization 350, and/or the temperature control instruction inserter/temperature control instruction insertion 360 and/or the iteration controller/iteration control 370 may be omitted. Accordingly, the user interface 340, the visualizer/visualization 350, the temperature control instruction inserter/temperature control instruction insertion 360 and/or the iteration controller/iteration control 370 may be considered as being optional.

In the following, some further details will be described.

The analyzer/analysis 320 is configured to receive the testing profile 310 (which may, for example, describe an evolution of a DUT temperature over time), or a preprocessed version 382 thereof. For example, a preprocessing block 380 may apply a filter or a filtering to the testing profile 310 and/or may apply a suppressor/suppression to the testing profile 310, to obtain a preprocessed testing profile 382. For example, the preprocessing block 380 may be configured to filter out (e.g., exclude) or to neglect thermal events (e.g., thermal peaks) having a comparatively smaller relevance (e.g., thermal events having a smaller likelihood to be relevant; e.g., thermal events having a smaller likelihood to affect a functionality of a device under test) from the testing profile, to thereby obtain the preprocessed testing profile 382. For example, the filter/filtering may use one or more “smart filters”, parameters of which are adjusted automatically and/or in dependence on a user interaction. For example, the optional filter/filtering in the preprocessing block 380 may reduce a noise on the testing profile, and/or may suppress thermal peaks that are considered as being of little relevance (e.g., due to their short duration and/or due their small amplitude, and/or due to their small integral area). Thus, the optional preprocessing block 380 may provide the analyzer/analysis 320 with a preprocessed testing profile, such that temperature control instructions can be obtained on the basis of the preprocessed thermal profile 382. In the preprocessed thermal profile 382, thermal events (e.g., thermal peaks) having a comparatively higher relevance (e.g., having a comparatively higher likelihood to be relevant; e.g., thermal events having a comparatively higher likelihood to affect a functionality of the device under test) are included while thermal peaks having a comparatively lower relevance (e.g. having a comparatively lower likelihood to be relevant; e.g. thermal events having a comparatively lower likelihood to affect a functionality of a device under test) are reduced or filtered out or suppressed.

To conclude, the analyzer/analysis 320 may (for example, automatically) analyze the testing profile 310, or the preprocessed testing profile 382, to thereby obtain an information 322 describing a plurality of temperature peaks like, for example, parameters of temperature peaks or parameters of fitting functions (fitting temperature peaks within the testing profile 310 or within the preprocessed version 382 of the testing profile 310).

The analyzer/analysis may, for example, obtain the information 322 describing temperature peaks using a fitting approach. In the fitting approach, respecting fitting functions, e.g., parametrized fitting functions, may be fitted to the thermal peaks within the testing profile 310 or within the preprocessed version 382 of the testing profile. In the fitting approach, parameters of one or more fitting functions may be determined. The fitting functions may, for example, be parabolic fitting functions, or Gaussian fitting functions, or normal distribution fitting functions, or Lorentzian fitting functions, or Voigt fitting functions. For example, parameters of the fitting functions may be determined such that the fitting functions approximate different peaks within the testing profile 310 or within the preprocessed version 382 of the testing profile.

For example, a “distance measure” may be evaluated during a fitting procedure, wherein the fitting procedure may, for example, be considered as an optimization of one or more parameters of a respective fitting curve (fitting function) in order to reduce or minimize a distance between the parameterized fitting curve (fitting function) and a corresponding portion of the testing profile. Thus, the analyzer/analysis 320 may be configured to determine one or more fitting function parameters per fitting function, such that the respective parametrized fitting functions approximate respective peaks within the testing profile 310, or within the preprocessed testing profile 382, with a sufficient accuracy (or quality).

During the fitting procedure, noise of the temperature peaks typically does not have a strong impact on the fitting result, since it is typically averaged out by a distance measure evaluating (or judging) the difference between the testing profile (or a portion of a testing profile) and a parameterized fitting function. Optionally, the curve fitting may be performed such that a common fitting function is fitted for two or more adjacent temperature peaks (e.g. partially overlapping temperature peaks). For example, by appropriately choosing the distance measure, a common fitting function may be fitted to two or more adjacent thermal peaks (provided that the adjacent thermal peaks are sufficiently close to each other).

Accordingly, the analyzer/analysis 320 provides an information 322 describing temperature peaks within the testing profile 310 or within the preprocessed testing profile 382. For example, the information describing temperature peaks may comprise one or more parameters of the temperature peaks, like, for example, respective timing parameters of the respective temperature peaks and/or respective amplitude parameters of the respective temperature peaks. For example, the analyzer/analysis 320 may use the parameters of the fitting functions as the parameters of the temperature peaks, or may derive the parameters of the temperature peaks from the parameters of the fitting functions. For example, the time of a peak of a fitting function may be considered as a time of a peak of a thermal peak. Moreover, a maximum value of a fitting function may be considered as a maximum value of a thermal peak (even though the thermal peak may actually comprise a slightly different maximum value). Worded yet differently, the different thermal peaks within the testing profile may be approximated by the fitting functions, and the respective parameters of the fitting functions may be considered as the parameters of the thermal peaks. Naturally, it is also possible that the parameters of the temperature peaks (thermal peaks) may be derived from the parameters of the fitting functions using some mapping or mapping function.

The temperature control instruction provider/temperature control instruction provision 330 receives the information about the temperature peaks (e.g., parameters of temperature peaks, or simply parameters of fitting functions determined by the analyzer/analysis 320) and provides, on the basis thereof, a plurality of temperature control instructions 332. For example, the temperature control instruction provider/temperature control instruction provision 330 may provide an instruction which activates a cooling or a heating. For example, the temperature control instruction provider/temperature control instruction provision 330 may determine parameters of such a temperature control instruction 332 on the basis of the information describing temperature peaks. As an example, the temperature control instruction provider/temperature control instruction provision 330 may determine one or more timing parameters, defining when a cooling or heating should be activated and/or when a cooling or heating should be deactivated on the basis of parameters of the fitting functions.

Just as an example, the temperature control instruction provider/temperature control instruction provision 330 may receive a parameter describing a time at which a peak of the fitting function occurs and may optionally also receive a parameter describing a width of the fitting function and may further optionally receive a parameter describing an amplitude of a fitting function. For example, the temperature control instruction provider/temperature control instruction provision 330 may derive a parameter describing a beginning of a cooling (or a beginning of a heating) on the basis of the parameter describing a time at which the peak of the fitting function occurs, and optionally also in dependence on a parameter describing a width (e.g., a temporal extension) of the fitting function. For example, the temperature control instruction provider may provide the parameter describing the timing of the cooling (or of the heating) such that the heating begins a certain time before the temperature peak (or even before a beginning of the temperature peak). However, the temperature control instruction provider 330 may also consider an amplitude of the temperature peak to determine a time at which the cooling (or heating) starts. To conclude, the temperature control instruction provider 330 may consider one or more parameters of the fitting functions to determine a start time parameter of a temperature control instruction (wherein the start time parameter may describe, for example, a time at which a cooling or a hearing should start).

Moreover, the temperature control instruction provider 330 may provide a parameter describing a cooling intensity or a heating intensity in dependence on one or more parameters of the fitting functions, for example in dependence on a parameter describing an amplitude (or a peak value) of a fitting function. However, other parameters of the fitting function may also be considered to determine the parameter describing the strength of the cooling or of the heating. Just as an example, if the parameter of a fitting function indicates that the fitting function has a long temporal extension, the intensity of the cooling or heating may be chosen longer than for the case that the parameter of the fitting function indicates a short temporal extension of the temperature peak.

To conclude, one or more parameters of a respective temperature control instruction may be determined in dependence on one or more parameters of a respective fitting function by the temperature control instruction provider 330. Just as an example, the testing profile may describe a temporal evolution of a DUT temperature, e.g., taking reference to a predetermined time reference. Moreover, the parameters of the temperature control instructions may also be related to this time reference.

The temperature control instruction inserter 360 may receive the temperature control instructions 332 and insert temperature control instructions into a test flow (which may, for example, also be designated as an initial test flow), to thereby obtain an updated test flow. Alternatively or in addition, the temperature control instruction inserter 360 may generate, e.g. in an iteration, a revised test flow, e.g. on the basis of the initial test flow or on the basis of the updated test flow.

The temperature control instruction inserter may, for example, receive the test flow in the form of a test program and may insert the temperature control instructions into such a test program. For example, the temperature control instruction inserter may obtain an information indicating which instructions (or tests or test suites) of the test program have been executed at which time. Accordingly, the temperature control instruction inserter may determine (e.g., on the basis of a timing parameter of a temperature control instruction) at which position within the test program the temperature control instruction should be inserted. For example, the temperature control instruction inserter 360 may receive a test log file which comprises an information which test program instruction (or which test defined in the test program, or which test suite defined in the test program) has been executed at which time (wherein, ideally, the time reference of the testing profile should be identical to the time reference of the test log file). Accordingly, the timing parameter of a temperature control information can be used, by the temperature control instruction inserter 360, to decide where within the test flow (or within the test program defining the test flow) the temperature control instruction should be inserted. Thus, the temperature control instruction inserter uses an information indicating at which time (in terms of real, physical time) an instruction (or test or test suite) is executed (or has been executed), for example to obtain the testing profile 310). It is decided, on the basis thereof, where within the test flow (e.g., within a test program defining the test flow) the temperature control instruction should be inserted. Accordingly, by inserting the temperature control instruction at an appropriate position within the test flow, a temporal coordination between the execution of the test flow and the active temperature control, defined by the temperature control instruction, is achieved.

In the following, additional functionalities are described which may be implemented in the automated test equipment 300.

The automated test equipment may comprise an (optional) temperature peak identifier/temperature peak identification 384, which may be configured to identify a plurality of temperature peaks in the testing profile 310 (or in the preprocessed version 382) using a temperature threshold value (which may, for example, be determined automatically or which may, for example, be set by a user) and/or in dependence on the extension (e.g., in dependence on an area; e.g., in dependence on an area of a time-temperature integral; e.g., in dependence on an area above a temperature threshold value) of respective temperature peaks.

Thus, the temperature peak identifier/temperature peak identification 384 may, for example, compare the temperature values of the testing profile with a temperature threshold value and thereby identify temperature peaks which exceed the temperature threshold value. Consequently, the temperature peak identifier/temperature peak identification 384 may provide an information 386 about identified temperature peaks to the analyzer/analysis 320 and the analyzer/analysis 320 may fit the respective fitting functions to the identified temperature peaks or to a subset of the identified temperature peaks, in order to obtain the information describing the plurality of thermal peaks. However, the analyzer/analysis 320 may, for example, leave signal portions which have not been identified by the temperature peak identifier/temperature peak identification 384 unconsidered, or the analyzer/analysis 320 may only fit respective fitting functions in portions of the testing profile around the identified temperature peaks described by the information 386. Accordingly, the computational effort for the fitting may be reduced by pre-selecting temperature peaks. Alternatively, however, the temperature peak identifier/temperature peak identification 384 may consider a “peak size” or “peak area”, or “peak extension” to decide whether a peak should be “identified” and used in a fitting approach. To conclude, the temperature peak identifier 384 may help to reduce a computation complexity needed for the fitting.

The automated test equipment optionally also comprises a classifier/classification 388 which is configured to receive the testing profile 310 and to provide, on the basis thereof, a classification information 390. The classifier is configured to classify thermal events (e.g., temperature peaks or thermal peaks) as thermal events having a small (or comparatively smaller) significance (e.g., thermal events having a smaller likelihood to be relevant; e.g., thermal events having a smaller likelihood to affect a functionality of a device under test) and as thermal events (e.g., temperature peaks or thermal peaks) having a high (e.g., comparatively higher) significance (e.g., having a comparatively higher likelihood to be relevant; e.g., thermal events having a comparatively higher likelihood to affect a functionality of the device under test). Consequently, the automated test equipment is configured to (selectively) obtain the temperature control instructions 332 (e.g. only) on the basis of the thermal events having the high significance (e.g., classified as having the high significance). On the other hand, thermal events classified as having the low significance may be left unconsidered, for example, by the analyzer/analysis 320.

Worded yet differently, the analyzer/analysis may use the information 390 about identified temperature peaks to decide which temperature peaks have been classified as being of sufficient significance. For example, the classifier/classification 388 may use one or more smart filters, parameters of which are adjusted automatically and/or in dependence on a user interaction, to perform the classification. For example, the classifier 388 may classify temporal peaks having a length that is shorter than a predetermined length, as being of low significance, such that such very short temperature peaks are left unconsidered by the fitting approach. However, different classification functions could also be used by the classifier 388, e.g., to classify temperature peaks having a certain shape as being of high significance or as being of low significance. Thus, the optional classifier/classification 388 may contribute to mark certain thermal peaks fulfilling certain criteria as being of high relevance and/or to mark certain peaks fulfilling certain criteria as being of low relevance. Consequently, the classification performed by the classifier 388 may be helpful to decide which temperature peaks should be considered in the fitting approach and/or which temperature peaks should be neglected in the fitting approach. Thus, a good efficiency of the fitting approach can be achieved. Just as an example, the classifier 388 could also consider rise times and/or fall times of the temperature peaks for the classification.

The automated test equipment comprises a user interface 340. The user interface may, for example, allow a user of the automated test equipment to set a variety of parameters. For example, the user interface may be configured to allow for a setting of parameters for the analyzer/analysis 320. Just as an example, the user interface 340 may allow for a selection of a type of the fitting functions and/or may allow for a setting of a maximum number of fitting functions and/or may allow for a selection of ranges for one or more parameters of the fitting functions. Optionally, the user interface may also allow for a selection of a maximum overheat event proximity parameter, which may, for example, define how close the temperature peaks may be to be identified as separate temperature peaks.

Moreover, the user interface 340 may also allow for a setting of one or more parameters for the filter/filtering 380. For example, the user interface may allow for a setting of one or more parameters describing which temperature peaks should be filtered out or suppressed. For example, the user interface may be configured to set a temperature threshold, such that temperature peaks which do not reach the temperature threshold are filtered out or suppressed, and are consequently not used by the analyzer/analysis 320.

Moreover, the user interface may also be configured to allow for a setting of one or more parameters of the temperature peak identifier/temperature peak identification 384. For example, the user interface may be configured to allow the user to set a threshold value for the temperature peak identifier/temperature peak identification 384 and/or an extension threshold parameter for the temperature peak identifier/temperature peak identification 384. The extension parameter may, for example, indicate that temperature peaks having an integral area below the threshold value will not be considered by the analyzer/analysis 320 for performing a fitting.

Moreover, the user interface may also be configured to input one or more parameters for the classifier/classification 388.

To conclude, the user interface 340 may be adapted to allow the user to have an influence on the analysis of the testing profile. The user may be able to set a single parameter, or may be able to set a plurality of different parameters to thereby control the components of the automated test equipment, in particular to control the functionality of the analyzer/analysis 320, the functionality of the filter/filtering 380, of the temperature peak identifier/temperature peak identification 384 and/or of the classifier/classification 388.

In particular, the user interface 340 may also cooperate with an automatic setting of the parameters of the above mentioned processing blocks. For example, the user interface 340 may allow the user to select which of the above mentioned parameters are determined automatically by the automated test equipment and which of the above mentioned parameters should be set manually. Accordingly, the flexible user interface 340 may, for example, allow the automated test equipment to largely automatically obtain the information describing the temperature peaks. On the other hand, the user interface 340 may give the experienced user the possibility to take manual control over one or more of the above mentioned parameters, to have a higher degree of manual control over the determination of the information describing the temperature peaks. In particular, the experienced user can combine an automatic determination of one or more of the above mentioned parameters with a manual setting of one or more other ones of the above mentioned parameters to thereby efficiently set the analysis algorithm.

Moreover, the automated test equipment 300 also comprises a visualizer/visualization 350. The visualizer/visualization 350 may, for example, visualize both the testing profile and the respective fitting functions obtained by the analyzer/analysis. Moreover, the visualizer/visualization may also visualize other parameters or results, like, for example, temperature control periods during which a heating or cooling is activated. However, the visualizer/visualization 350 may also include one or more parameters or parameter settings into the visualization. Furthermore, the visualizer/visualization may include information from the test flow and/or from the test log file into the visualization. Accordingly, the visualizer/visualization 350 may give the user a graphic representation of the testing profile, wherein the user can see a temporal relationship between an execution of test instructions (e.g., tests or test suites) and temperature peaks.

Moreover, the visualizer/visualization 350 may, for example, be configured to update the representation of the testing profile and/or the representation of the fitting functions and, optionally, the representation of further results in quasi-real time. For example, the visualizer/visualization 350 may provide a user with quasi-instantaneous visual feedback how changes of one or more user settings via the user interface affect the results, e.g., the fitting functions and/or the temperature control instructions. Accordingly, the graphical representation of both the testing profile and of the results of the analysis help the user to properly adjust user settings and to obtain temperature control instructions (or a test flow including such temperature control instructions) that result in a reliable test.

Thus, the automated test equipment 300 according to FIG. 3 provides both unexperienced and experienced users the chance to obtain an updated test flow with temperature control instructions inserted at appropriate places. The automated test equipment 300 may, for example, even allow for an automatic generation of such an updated test flow in some cases. On the other hand, the automated test equipment 300 may support both unexperienced and experienced users to properly adjust user settings and to thereby obtain a best possible updated test flow.

Moreover, it should be noted that the automated test equipment 300 according to FIG. 3 may optionally be supplemented by any of the features, functionalities and details described herein, both individually and taken in combination.

Moreover, it should be noted that any of the features, functionalities and details described with respect to the automated test equipment 300 may optionally be introduced into any of the other embodiments, both individually and taken in combination.

### Further Embodiments and Aspects

In the following, further embodiments and aspect of the present invention will be described. These features, functionalities and details may optionally be used in any of the embodiments disclosed herein, both individually and taken in combination.

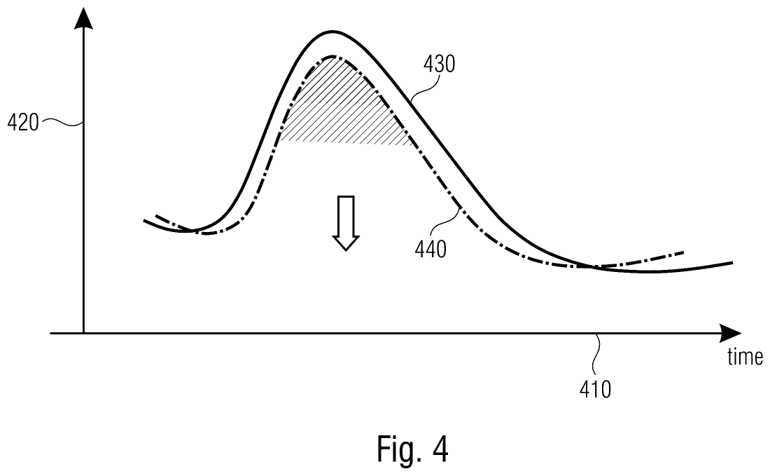

FIG. 4 shows a graphic representation of a desired reduction of the DUT temperature. An abscissa 410 describes a time and an ordinate 420 describes a DUT temperature. A first curve 430 describes a DUT temperature which would be present in the absence of an active temperature control.

A second curve 440 shows a DUT temperature which can be achieved in the presence of an appropriate active temperature control. It can generally be seen from FIG. 4 that it is an objective of embodiments of the present invention to reduce a DUT temperature to an acceptable level and to reduce an amplitude of temperature peaks.

In the following, the purpose of embodiments according to the present invention will be described.

In the context of the present invention, it is assumed that handlers are equipped with active thermal control (ATC). However, in many cases, response time is lagging to a rapid thermal excursion.

Embodiments according to the invention (e.g., the inventive method) use predictive response, i.e., the anticipated thermal profile is already known and the software uses smart algorithms to automatically calculate which thermal peaks to address, thus programming the hander and test flow to start cooling before anticipated thermal feed excursion.

A software development concept of a previous proposal is shown by Yoshino Takatoshi in VOICE 2019. Reference is made, for example, to “PRODTEST-218-HSI-New Solution Improvement for Device Temperature Analysis Synchronized with the Test Program, X ZHAO, NVIDIA; Takatoshi Yoshino, Hideki Ichikawa, Takashi Hashimoto and T. K. Chen, ADVANTEST”.

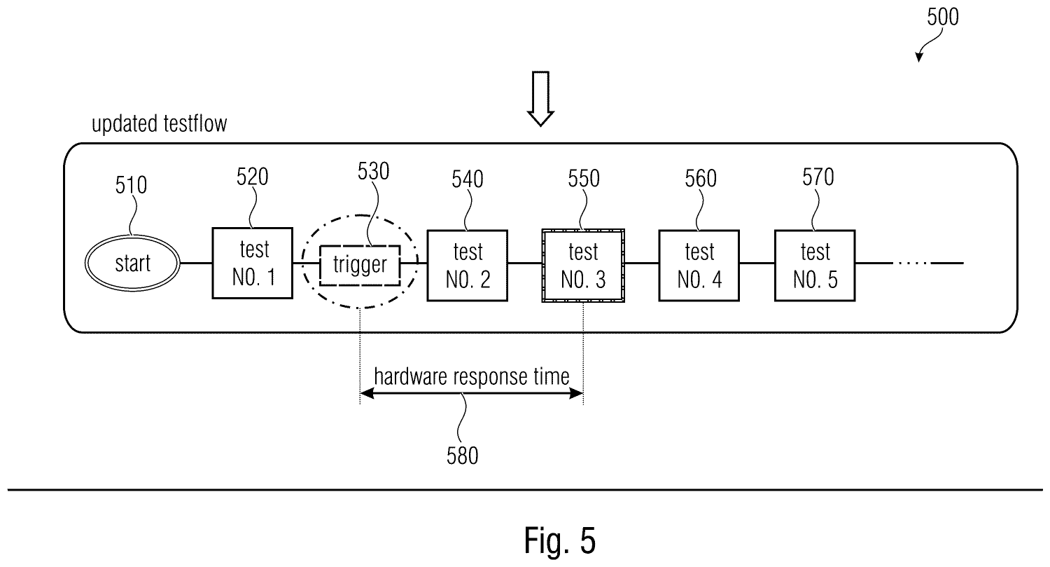

In the following, the concept to provide an updated test flow, which can optionally be used in embodiments according to the invention, will be described taking reference to FIG. 5.

FIG. 5 shows a graphical representation of an updated test flow. The test flow starts at a starting point 510. After the starting point, a first test 520 is executed. After the first test 520, a trigger 530 is inserted in the test flow. After the trigger 530, a second test 540 is executed. After the second test 540, a third test 550 is executed. Subsequently, further tests 560, 570 are executed. However, for the purpose of the explanation, it is assumed that the third test 550 causes a temperature peak that should be eliminated or reduced. In view of the fact that the cooling hardware comprises a hardware response time 580, a trigger 530 is introduced into the test flow between the first test 530 and the second test 540. In other words, it becomes apparent that the trigger 530, which may, for example, be a temperature control instruction that activates a cooling, has not been inserted right before the third test 550 but before the second test 540. Accordingly, it can be assumed that the cooling that is triggered by the trigger 530 starts a certain time before the start of the third test 550 (wherein this time may, for example, be determined by the execution time of the second test 540). It is thus apparent that the trigger 530 (e.g., a temperature control instruction) is, for example, inserted into the updated test flow (e.g., into the updated test flow 318 provided by the automated test equipment 300) at a position within a test flow that is determined, for example, by a predetermined (or assumed) hardware response time and a time at which the temperature peak caused by the third test 550 has been identified.

Thus, the automated test equipment 100 or the automated test equipment 200 or the automated test equipment 300 may generate a temperature control instruction (e.g., the trigger 530) in response to an analysis of a test profile which indicates the temperature peak caused by the third test 550. This temperature control instruction may, for example, be inserted into a test flow by a temperature control instruction inserter/temperature control instruction insertion (e.g. by the temperature control instruction inserter/temperature control instruction insertion 360 of the automated test equipment 300), wherein the temperature control instruction inserter may, for example, make use of a test log file (e.g. the test log file 316) and/or may make use of the predetermined or assumed hardware response time 580.

Accordingly, an updated test flow 500 can be achieved, which may, for example, correspond to the updated test flow 318 obtained by the temperature control instruction inserter 360.

Accordingly, the embodiments according to the present invention can, for example, fulfil the requirement to bring a solution for testing high performance compute DUTs, avoiding DUT over-heating thermal excursion, enabling “safe” testing inside a thermal range of allowed DUT operations.

Moreover, embodiments according to the invention provide a concept which is one step ahead of alternative concepts (e.g., competitors' concepts) in term of solution (Cohu).

Generally speaking, it can be said that it is a target of embodiments according to the present invention to improve device testing for customers in high performance computer business segments using handlers, which are equipped with active thermal control (ATC).

For example, the testing profile, which may describe a temporal evolution of the DUT temperature, may be obtained by performing a test of a device under test by monitoring the DUT temperature during such a test, and the temperature control instructions that are provided by the automated test equipment (or an updated test flow that is provided by the automated test equipment) may be used in another test of a device under test, where it may, for example, be assumed that the temperature control instructions (which may, for example, be included in the updated test flow) are used to control the active temperature control (ATC) within the handler (which places the DUT in a test socket and which typically includes a cooling functionality and/or a heating functionality).

In the following, a brief overview over embodiments according to the present invention will be provided. In particular, a listing of functionalities, which are performed by embodiments according to the invention will be provided.
1. DUT thermal profile (e.g., testing profile 110, 210, 310) is recorded (e.g., during a execution of a test of the DUT) and loaded into the software (e.g., into the software of the automated test equipment 100, 200, 300);
2. Thermal profile (e.g., testing profile 110, 210, 310) and (optionally) test flow EDL data (e.g., a test log file describing which test or test suite is started, or executed at which time) is loaded into software (e.g., into the software of the automated test equipment 100, 200, 300).
3. Smart features are applied (optional):
   Software SW calculates which are the most likely thermal events that are relevant to apply cool down for:
   Smart filters are applied to exclude thermal events that are not relevant.
4. Mathematical model is run and thermal peaks are smartly assigned for those exceeding the DUT threshold temperature (also can be automatically detected or specified by user).
5. Cooling parameters timing/duration/strength are automatically calculated.
6. New test flow is generated (optional)—with pre-trigger cooling signals for problematic test suites causing over-heat.
7. Overlay cooled down thermal profile (optional).

For example, step 1 mentioned above may be executed by performing test of the device under test, wherein the DUT thermal profile (e.g., a temporal evolution of the DUT temperature) may be recorded as a “testing profile”. This testing profile 110, 210, 310 may be loaded into the software of the automated test equipment 100, 200, 300.

For example, step 2 mentioned above may be implemented by loading the thermal profile (e.g., the testing profile) into the software of the automated test equipment, and by also loading a test log file (which may be considered as “EDL data”) into the software of the automated test equipment.

For example, step 3 “smart features” may be implemented by applying the filter/filtering 380 onto the testing profile, to thereby obtain a preprocessed version of the testing profile. The step 3 may alternatively or in addition be implemented using the temperature peak identifier/temperature peak identification 380 in which the largest thermal peaks (e.g., thermal peaks having a maximum temperature and/or thermal peaks having a maximum extension) are identified. Moreover, step 3 may also be implemented using the classifier/classification 388, which may classify temperature peaks as being of lower relevance or as being of higher relevance. To conclude, different processing functionalities 380, 384, 388 may, for example, be used to determine which thermal events (e.g., temperature peaks) are relevant and which thermal events (e.g., temperature peaks) can be neglected.

For example, step 4 as mentioned above can also comprise a selection of thermal events (e.g., temperature peaks) which appear to be relevant. Assigning thermal peaks may, for example, be performed by the analyzer/analysis 320 using the fitting approach, wherein fitting curves are fitted temperature peaks within the testing profile or within the preprocessed testing profile.

For example, step 5 (automatic calculation of cooling parameters) may be performed by the temperature control instruction provider 330, wherein parameters of the fitting curves may, for example, be used to determine the cooling parameters (like timing, duration, and strength).

For example, step 6 mentioned above may, for example, be performed by the temperature control instruction inserter/temperature control instruction insertion 360 which inserts the temperature control instructions 332 into the test flow 314 at appropriate times. For example, the updated test flow 318 may be the “new test flow”. The temperature control instructions may be inserted into the test flow 314 in such a manner that they can be considered as “pre-trigger cooling signals”. For example, the temperature control instructions can be inserted temporally before problematic test or problematic test suits, for example, with a temporal distance in between. For example, the temperature control instructions 332 may be inserted into the test flow as shown in FIG. 5, wherein the temperature control instructions may take the place of the “trigger” 530, and wherein one or more “unproblematic” test (like the second test 540) may be in between the respective temperature control instructions and the test causing a temperature peak (like, for example, the test 550).

For example, step 7 may comprise performing a test using the new test flow (updated test flow).

Moreover, it should be noted that steps 1 to 7 discussed above may optionally be used in any of the embodiments according to the present invention. However, it should also be noted that steps 1 to 7 as described above can be used both in the described form and may also be supplemented by any of the features, functionalities, and the details described herein, both individually and taken in combination.

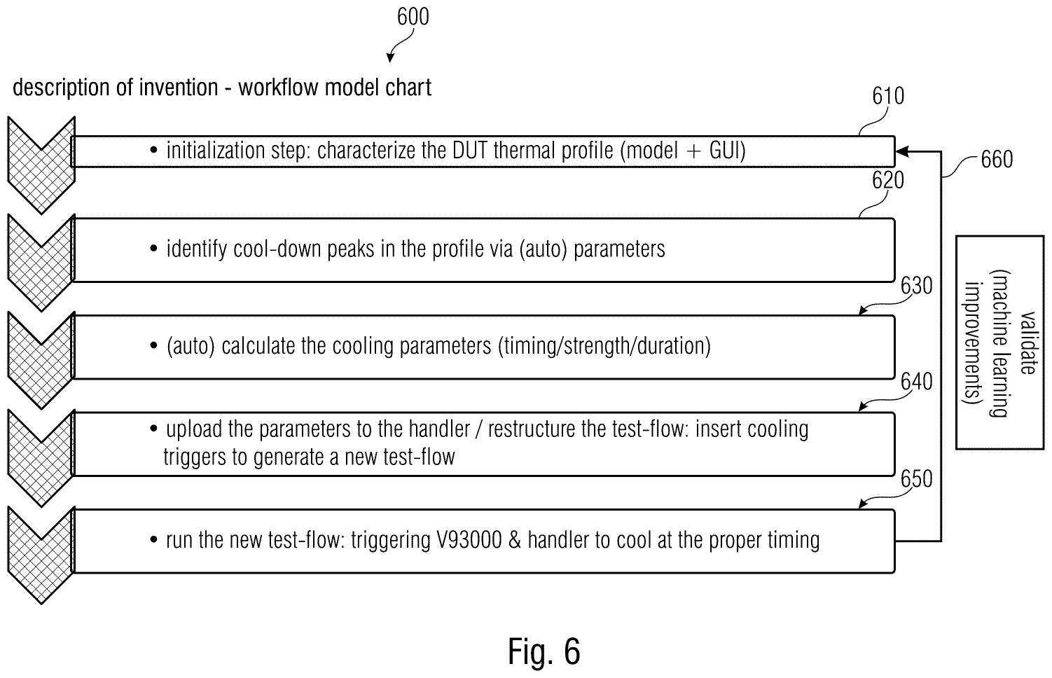

In the following, a functionality of the embodiments of the invention will be described taking reference to FIG. 6.

FIG. 6 shows a workflow model chart of the inventive concept, according to an embodiment of the present invention. The workflow comprises a first step 610, which is an initialization step. The step 610 comprises characterizing the DUT thermal profile (model plus GUI). For example, in the initialization step, the behavior of the DUT may be modeled, to thereby obtain a “testing profile” describing the temporal evolution of the DUT temperature. Alternatively, the initialization step 610 may comprise measuring the DUT temperature over time during a test of the DUT (wherein, for example, during said test of the DUT, a cooling or heating may remain constant or may remain unaffected by a time-variable active thermal control).

The workflow comprises a second step 620 of identifying cool-down peaks in the profile (e.g., in the thermal profile or in the “testing” profile) via (auto) parameters. For example, in the second step 620, temperature peaks may be identified, wherein the identification of such temperature peaks may be performed using parameters that may be set manually or that may be set automatically. Automatic parameter setting may, for example, comprise setting a temperature threshold such that there is a predetermined number of peaks (or of separate peaks having at least a predetermined distance) that exceed the temperature threshold value. However, a temperature threshold value could be set manually, for example, using a user interface of the automated test equipment.

The workflow further comprises a third step 630 of calculating (or auto-calculating) the cooling parameters (e.g., timing/strength/duration). For example, the cooling parameters can be automatically calculated on the basis of the identified cool down peaks. For example, parameters of the identified cool down peaks can be determined, wherein, for example, a curve fitting can be applied to determine the parameters of the identified peaks. For example, respective fitting curves can be fitted to the identified temperature peaks within the thermal profile (or testing profile). Parameters of the fitted curves can then be used to derive the cooling parameters. Accordingly, for example, temperature control instructions 332 may be generated, wherein the “cooling parameters” may be included in a set of temperature control instructions.

The workflow also comprises a fourth step 640 of uploading the parameters to the handler/restructuring the test flow: insert cooling triggers to generate a new test flow. For example, in the fourth step, the parameters (e.g., the cooling parameters) may be uploaded to the handler. For example, the handler may receive from the automated test equipment a plurality of sets of cooling parameters, wherein the handler may, for example, be configured to apply said sets of cooling parameters in response to trigger signals from the automated test equipment. For example, each trigger signal from the automated test equipment may cause the handler to use a new set of cooling parameters. Moreover, the fourth step may comprise restructuring the test flow, wherein, for example, “cooling triggers” (e.g., instructions to send a trigger signal to the handler) are inserted into the test flow to generate a new test flow (or an updated test flow, or a revised test flow). Thus, there may, for example, be a correspondence between temperature control parameters (e.g., cooling parameters) uploaded to the handler and cooling triggers inserted into the new test flow (or updated test flow, or revised test flow), such that each cooling trigger triggers the usage of a new temperature control parameter or set of temperature control parameters.

The workflow 600 may also comprise a fifth step 650 of running the new test flow, which comprises triggering the V93000, (e.g., the automated test equipment) and handler to cool at the proper timing. In other words, for example, running the new test flow (e.g., the updated test flow or revised test flow 318) comprises triggering the automated test equipment (e.g., an automated test equipment of type V93000) and also triggering the handler to cool at a proper timing. For example, triggering the handler to cool at the proper (desired) timing may comprise providing triggers (or trigger signals) from the automated test equipment to the handler in response to “cooling triggers” inserted into the new test flow in the fourth step. Accordingly, the triggers may cause the handler to apply a new set of cooling parameters (or temperature control parameters) whenever a trigger signal is received by the handler. Thus, for example, the new test flow may be run using active thermal control that is determined by the cooling parameters calculated in the third step. Consequently, an improved temperature control can be exercised on the device under test during the run of the new test flow (e.g., when compared to the execution of the original test flow in the first step 610).

Moreover, the workflow 600 comprises an iteration 660, wherein the workflow is continued with the first step 610 after the execution of the fifth step. In other words, when running the new test flow (as described in the fifth step 650), an updated thermal profile (or updated testing profile) is obtained. In this updated thermal profile, the active temperature control is considered (e.g. since active temperature control is used during the recording of the updated thermal profile). However, it can be expected that, due to some changes of the testing conditions (e.g. due to a change of a test timing caused by the active temperature control), the updated DUT thermal profile still comprises some temperature peaks. Consequently, the workflow continues with a re-execution of steps 620 to 650, wherein an update of the cooling parameters is determined on the basis of temperature peaks within the updated thermal profile. Accordingly, updated temperature control parameters (or revised temperature control parameters) can be obtained in the iteration.

However, it should be noted that the iteration may, alternatively or in addition, be used to validate the new test flow generated in the fifth step 650. Thus, it may, for example, be checked in an iteration (e.g., using a determination of an updated thermal profile or a testing profile), whether the new test flow (or updated test flow, or revised test flow) brings along a DUT temperature which remains within the needed limits.

However, alternatively or in addition, the iteration 660 may, for example, also be used to generate machine learning improvements. In other words, the iteration 660 may be used to iteratively improve the active temperature control (e.g., by improving the temperature control instructions).

However, it should be noted that the workflow as described in FIG. 6 may optionally be used in any of the embodiments disclosed herein. In particular, it should be noted that one, several, or all steps of the workflow 600 may optionally be introduced into any of the embodiments described herein.

However, it should also be noted that the workflow 600 may be used as a self-consistent embodiment according to an aspect of the invention. Furthermore, the workflow 600 may optionally be supplemented by any of the features, functionalities, and details disclosed herein, also with respect to the automated test equipment.

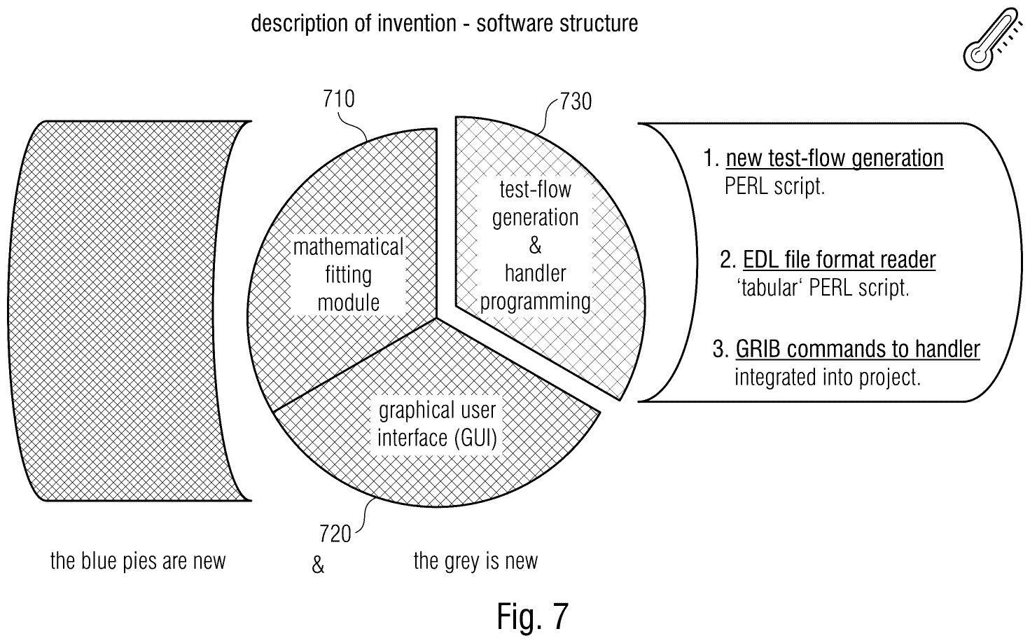

In the following, a software structure will be described taking reference to FIG. 7. In particular, it should be noted that FIG. 7 shows a schematic representation of a software structure, according to an embodiment of the present invention.

For example, the software structure described with reference to FIG. 7 can be used in any of the automated test equipment disclosed herein, for example, in the automated test equipment 100 or in the automated test equipment 200 or the automated test equipment 300.

The software structure comprises, among other functionalities, a mathematical fitting module 710. The mathematical fitting module 710 may, for example, be used in the testing profile analyzer/testing profile analysis 120 or in the testing profile analyzer/testing profile analysis 120 or in the analyzer/analysis 320. For example, the mathematical fitting module may be used to fit a plurality of fitting curves to temperature peaks within the testing profile.

Moreover, the software structure also comprises a graphical user interface (GUI) 720. The graphical user interface 720 may, for example, be used in the automated test equipment to receive user input from a user of the automated test equipment. For example, the graphical user interface 720 may be used to receive one or more parameters or parameter settings from a user of the automated test equipment. The parameter settings may also be considered as “user settings”. Moreover, the graphical user interface 720 may also be used to visualize both input quantities and output quantities of the automated test equipment. For example, the graphical user interface 720 may be used to visualize the testing profile and to also visualize respective fitting functions (e.g., fitting functions fitted to the testing profile).

Optionally, the graphical user interface may visual further settings, e.g., threshold levels, recognized temperature peaks, temperature control periods, and the like. For example, the graphical user interface 720 may implement the functionalities of the user interface 340 and the functionalities of the visualize/visualization 350. However, it should be noted that the graphical user interface 720 may also be used to implement other functionalities and/or additional functionalities.

The software structure also comprises a test flow generation and handler programming 730. The test flow generation and handler programming 730 may, for example, take over the functionality to obtain the temperature control instructions and/or to provide an updated test flow on the basis of an original test flow. For example, the test flow generation and handler programming may take the functionality of the temperature control instruction inserter/temperature control instruction insertion 360. However, the test flow generation/handler programming 730 may also comprise the functionality to send temperature control parameters (or sets of temperature control parameters) to a handler, wherein a usage of the respective sets of temperature control parameters by the handler will be triggered by a trigger signal provided to the handler by the automated test equipment (e.g., under the control of a test flow in which such “trigger” commands are inserted).

Moreover, it should be noted that the test flow generation and handler programming 730 may, for example, be implemented using different concepts. For example, the new test flow generation may be implemented using a PERL script. Moreover, an EDL file format reader (which may, for example, read a test log file) may be implemented using a “tabular” PERL script.

Moreover, a functionality of sending GPIB comments to the handler may also be integrated into the project.

To conclude, the software structure, which may be implemented in the automated test equipment, may comprise multiple components which may, for example, be in close interaction. A mathematical fitting module 710 may be controlled by parameters, which are input via the graphical user interface 720, and the graphical user interface 720 may also visualize (e.g., display) results provided by the mathematical fitting module (e.g., fitting functions). Moreover, results of the mathematical fitting module may be used in the test flow generation and handler programming 730, in order to obtain an updated test flow.

Moreover, it should be noted that any of the features, functionalities and details described with respect to the software structure may optionally be used in any of the other embodiments disclosed herein, both individually and taken in combination. In particular, the software structure described herein, and any features, functionalities, and details thereof, may optionally be used in any of the automated test equipment disclosed herein, both individually and taken in combination.

In the following, a graphical user interface according to an aspect of the invention will be described. For example, a user friendly interface “RH 7.4” may be used according to embodiments of the present invention.

The user interface may, for example, be used for leading a thermal profile (or testing profile) and EDL data (e.g., a test log file). Moreover, the graphical user interface may also be used for an auto detection of peaks (or for providing settings that may be used in an automatic detection of temperature peaks).

Moreover, the graphical user interface may also be used to program a new test flow and may comprises a handler (or a handling) for pre-cooling events.

To conclude, the graphical user interface may, for example, be used to control the operation of the automated test equipment.

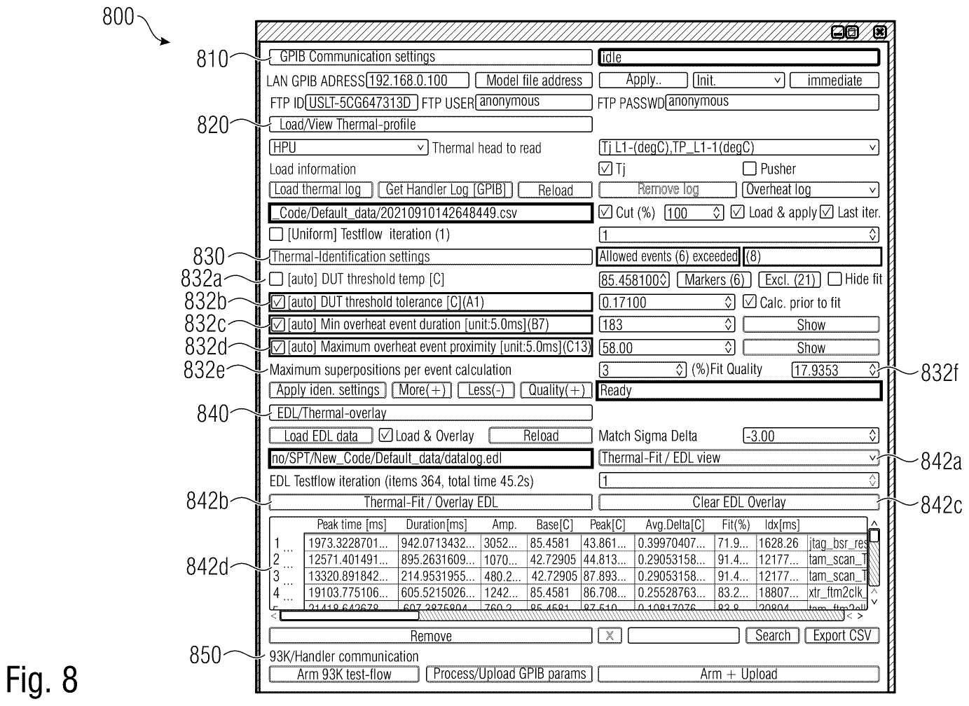

In the following, some details of the graphical user interface will be described taking reference to FIGS. 8, 9, 10a, 10b, 11, 14 and 15. For example, FIG. 8 shows a graphical representation of a user interface 800, which may be used in embodiments according to the invention. In particular, the graphical user interface as shown in FIG. 8 may be used in an automated test equipment according to the present invention.

As can be seen in FIG. 8a, the graphical user interface comprises GPIB communication settings 810, load/view thermal profile settings 820, thermal identification settings 830, EDL/thermal-overlay settings 840 and 93K/handler communication settings 850.

For example, the GPIB communication settings 810 may be used to set communication parameters for communication with the handler.

The load/view thermal profile settings 820 are used to load thermal profile information (or testing profile information) from the handler. For example, in the load/view thermal profile settings 820, it can be determined which thermal information is read. For example, it can be adjusted whether a junction temperature and/or a pusher temperature (e.g., of a pusher pushing the device under test into a device under test socket) are read from the handler and further processed by the automated test equipment. Accordingly, the load/view thermal profile information may be used to obtain a proper testing profile (i.e., an information describing an evolution of a relevant DUT temperature over time).

The thermal identification settings 830 allow to control an identification of temperature peaks within the thermal profile, or within a preprocessed thermal profile. Moreover, the thermal identification settings 830 may also be used to set parameters of the optional filter/filtering 380, of the optional temperature peak identifier/temperature peak identification 384 and/or of the optional classifier/classification 388. For example, the thermal identification settings may comprise a DUT threshold temperature settings 832a, a DUT threshold tolerance setting 832b, a minimum overheat event duration setting 832c and a maximum overheat event proximity setting 832d. Moreover, a maximum superposition per event calculation setting 832e and a fit quality setting 832f may be provided. For example, the DUT threshold temperature setting 832a may allow for an adjustment of a threshold temperature for identifying temperature peaks. Moreover, the DUT threshold tolerance setting 832b may, for example, also be used for an identification of temperature peaks. Furthermore, the minimum overheat event duration setting 832c may, for example, be used to determine a minimum duration of overheat events that will be identified as temperature peaks. For example, overheat events that are shorter than a duration specified by the minimum overheat event duration setting 832c may be neglected. Moreover, for example, the maximum overheat event proximity setting 832d may be used to decide whether overheat events which are close to each other are identified as a single overheat event or as separate overheat events. For example, overheat events, which are temporally closer than specified by the maximum overheat event proximity setting may be considered as a single temperature peak. Moreover, the “maximum superposition per event calculation” parameter 832e may be used to control how thermal peaks will be approximated.

Furthermore, it should be noted that the DUT threshold temperature setting 832, the DUT threshold tolerance setting 832b, the minimum overheat duration setting 832c and the maximum overheat event proximity setting 832d may be set manually, or may be set automatically. For example, a user may be allowed to decide for each of said settings whether an automatic setting or a manual setting is desired.

Moreover, the user interface may allow for further settings, like for example, a fitting quality setting 832f, which may, for example, define how good a fitting function should be fitted to the testing profile. To conclude, the thermal identification settings 830 allow the user of the automated test equipment to define how thermal peaks within the testing profile are identified and how the fitting functions are determined.

The EDL/thermal-overlay settings allow for specifying an EDL file (e.g., a test log file). The EDL/thermal overlay settings comprise, among other settings, a view setting 842a, which allows adjusting a type of data presentation. For example, a user may select that it is displayed which function (e.g. which test or test suite) of a test flow is being executed at a beginning of a fitting function. However, different viewing modes may optionally be selectable. Moreover, a button 842b may allow the user to activate an overlay of the test log data over a thermal fit, and a button 842c may allow the user to disable the overlay of the test log data.

A table 842d may provide the user with information about thermal peaks (or fitting functions approximating thermal peaks). The table 842d may also comprise references (or names) of functions that are executed at the time of the temporal peaks (wherein the latter information may, for example, be obtained by the automated test equipment on the basis of the EDL file or test log file). For example, the table 842d may comprise a peak time information, a peak duration information, a peak amplitude information, a base temperature information, a peak temperature information, an average delta temperature information, and a fit quality information. Thus, from the table 842d, a user may gain information about the identified temperature peaks and about the test or test suite running at the time of the peak.

EDL/thermal-overlay portion of the user interface may also provide functionalities to display or remove the thermal peaks and to export data for an external use.

Moreover the 93K (93000)/handler communication 950 may, for example, allow the user to control an upload of a test flow to the automated test equipment and/or to the device under test and/or to control an execution of a test flow.

To conclude, the user interface 800 according to FIG. 8 allows the user to control the identification of thermal peaks and the determination of temperature control instructions (which may, for example, include a fitting of fitting functions to the testing profile).

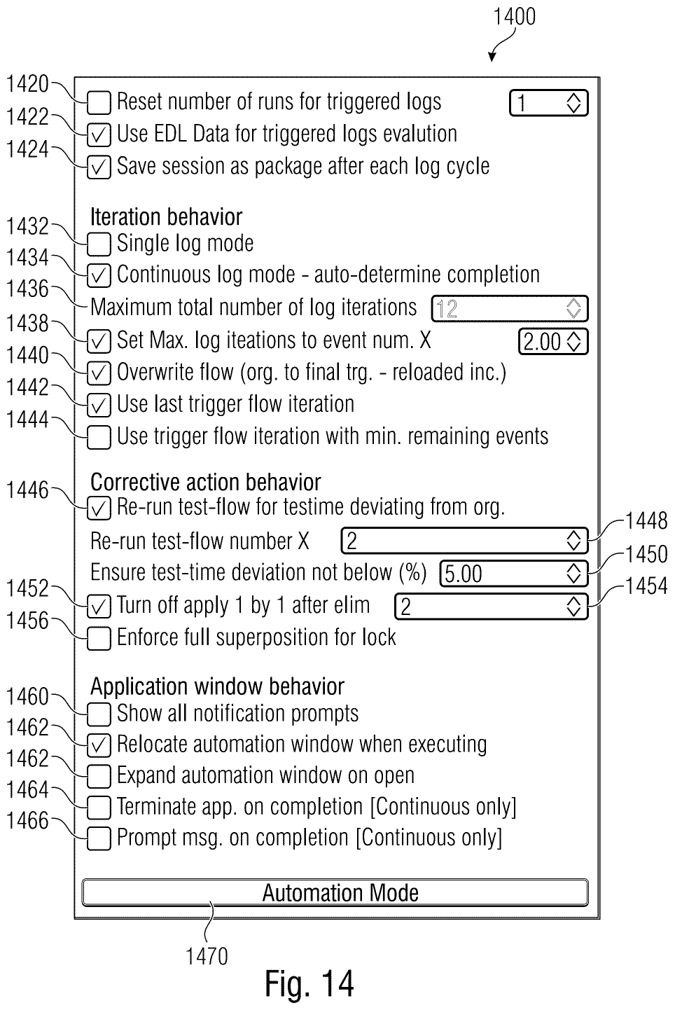

Moreover, details of an iterative determination of the temperature control instructions can be adjusted using the user interface according to FIG. 14, which will be described below.

However, it should be noted that the different settings shown in FIG. 8 should be considered as examples only, and that the user interface could naturally be designed in a different manner. Moreover, the user interface may naturally only comprise a part of the settings and indications mentioned above.

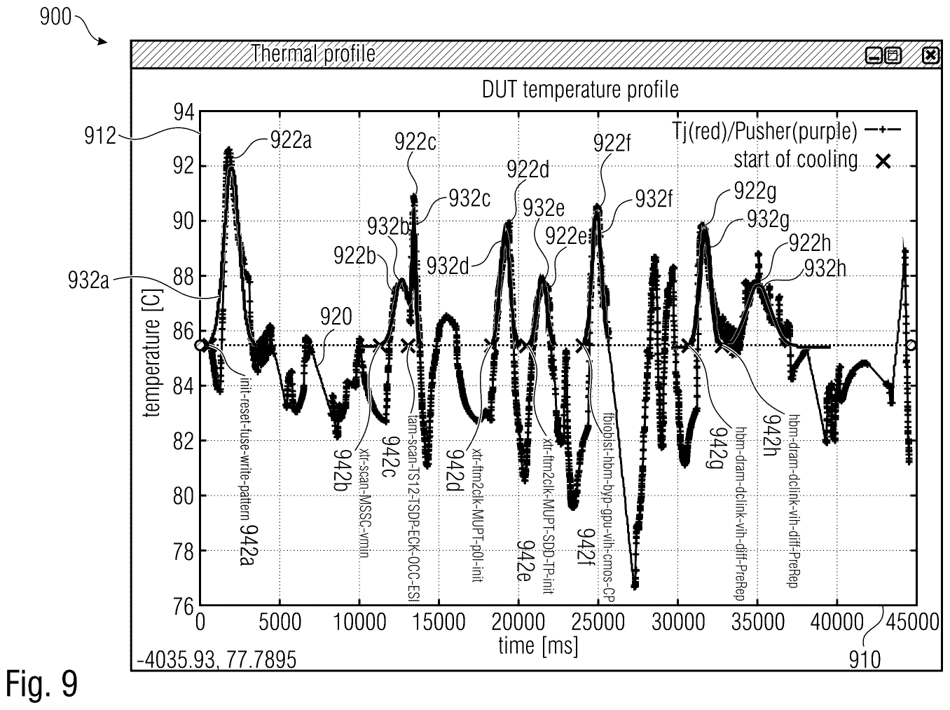

FIG. 9 shows a graphic representation of the testing profile, of fitting functions fitted to the testing profile, and of functions executed at the beginning of the fitting functions.

For example, an abscissa 910 describes a time, and an ordinate 912 describes a temperature (e.g. a DUT temperature or a handler temperature). A first curve 920 describes a junction temperature of the device under test. However, it should be noted that, alternatively, a temperature of a pusher or of the handler could also be shown. As can be seen, the temperature profile 920 shows a number of peaks and dips (which are, for example, considered as negative peaks). For example, a first peak is designated with 922a. A first fitting function 932a is also shown, wherein the first fitting function 932a is fitted to first temperature peak 922a. Moreover, further fitting functions 932b, 932c, 932d, 932e, 932f, 932g, 932h are fitted to further temperature peaks of the testing profile. Moreover, the graphic representation 900 also shows names of functions which are, for example, executed at the time of the beginning of the respective fitting functions.

It should be noted that the graphic representation 900 may, for example, be generated automatically by the automated test equipment. For example, the testing profile, which is represented by the curve 920, may be obtained by the automated test equipment, and the fitting functions 932a to 932h may be fitted to the testing profile by the automated test equipment (e.g. under the control of the user interface, or, alternatively, partly or fully automatically).

Moreover, the names of the functions which are executed at a time of the beginning of the fitting functions may, for example, be determined by the automated test equipment on the basis of the test log file and taking into consideration timing parameters of the fitting functions. In particular, it should be noted that the graphic representation 900 may be provided to a user by the automated test equipment to support the user with an appropriate setting of parameters (e.g. one or more of the parameters shown in FIG. 8).

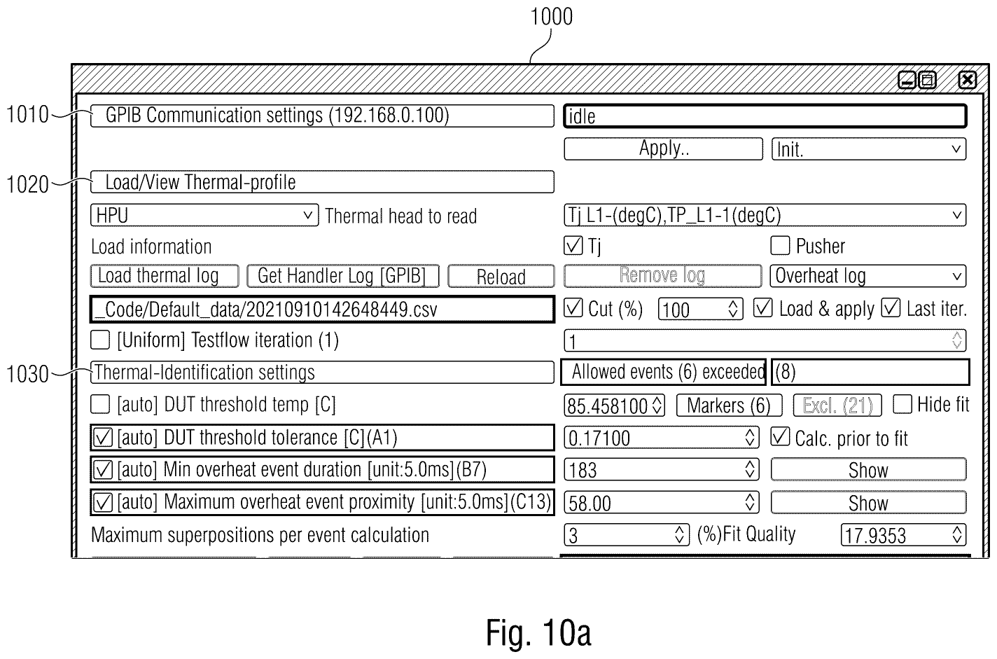

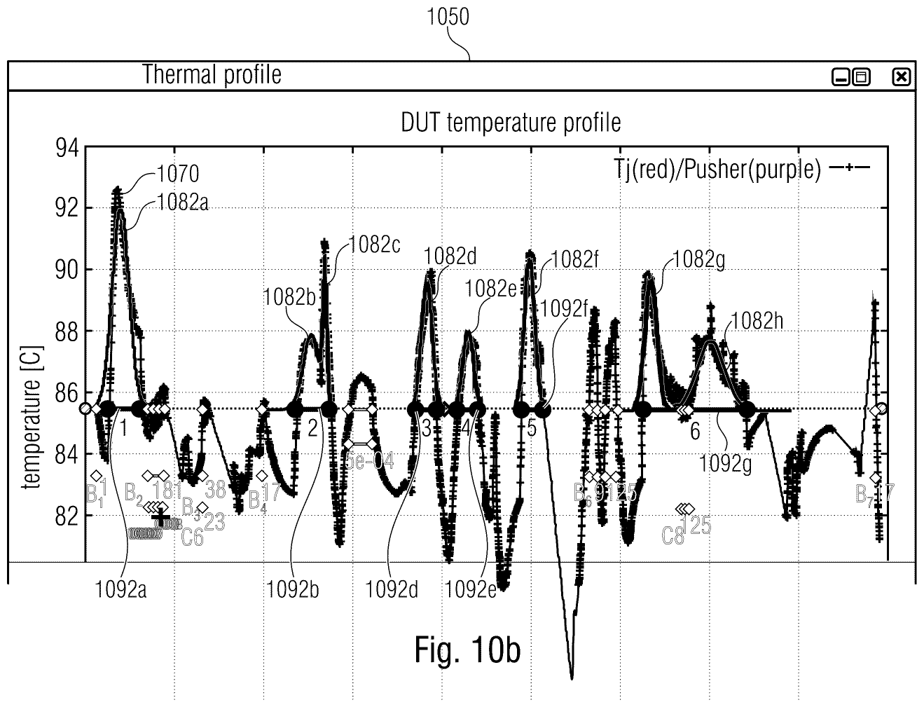

FIG. 10a shows a graphical representation of a user interface, according to an embodiment of the present invention. It should be noted that the user interface 1000 according to FIG. 10a (which may be a window of an overall user interface) may be similar to the user interface 800 according to FIG. 8. For example, the user interface 1000 also comprises GPIB communication settings 1010 which may correspond to the GPIB communication settings 810. Moreover, the user interface 1000 comprises load/view profile settings 1020, which may correspond to the load/view profile settings 820. Furthermore, the user interface 1000 also comprises thermal identification settings 1030 which may, for example, correspond to the thermal identification settings 830.

However, FIG. 10b also shows a graphic representation of a user interface 1050 (e.g. a window of the overall user interface). For example, the user interface 1050 according to FIG. 10b may represent the results of the settings that are provided in the user interface 1000 according to FIG. 10a. For example, a first window representing a user interface 1000 and a second window representing a user interface 1050 (which may, for example, both belong to an overall user interface) may be displayed simultaneously to a user of the automated test equipment.

Accordingly, the user interface 1050, according to FIG. 19b, may present (to a user) a curve 1070 which represents a thermal profile and may also represent identified fitting functions 1082a, 1082b, 1082c, 1082d, 1082e, 1082f, 1082g, 1082h. Moreover, the user interface 1050 further shows temperature control periods 1092a, 1092b, 1092d, 1092e, 1092f, 1092g. Regarding this issue, it should be noted that a common temperature control period 1092b has been associated for two fitting functions 1082b, 1082c which are sufficiently close. Similarly, a common temperature control period 1092g has been provided for two adjacent fitting functions 1082g, 1082h. In other words, even though the automated test equipment has fitted separate fitting functions 1082b, 1082c to two peaks of the testing profile, a common (single) temperature control period (and, for example, only a single temperature control instruction) has been associated to these two closely adjacent temperature peaks or to these two closely adjacent fitting functions. Similarly, the automated test equipment may have provided only a single temperature control instruction for the two adjacent peaks or for the two adjacent fitting functions 1082g, 1082h. For example, by an appropriate setting of the maximum overheat event proximity setting, the automated test equipment may be set to provide common temperature control instructions for multiple peaks or for multiple fitting functions. Accordingly, a number of temperature control periods, or equivalently, temperature control instructions, can be kept reasonably small even in the presence of a significant number of temperature peaks. Moreover, it should be noted that “negative” peaks have not been considered in the present example. However, it would naturally be possible to provide temperature control instructions (e.g. heating instructions) for the “negative” temperature peaks.

Moreover, it should be noted that the visualization provided by the user interface 1050 may, for example, respond to changes of parameter settings in the user interface 1000 in quasi-real-time.

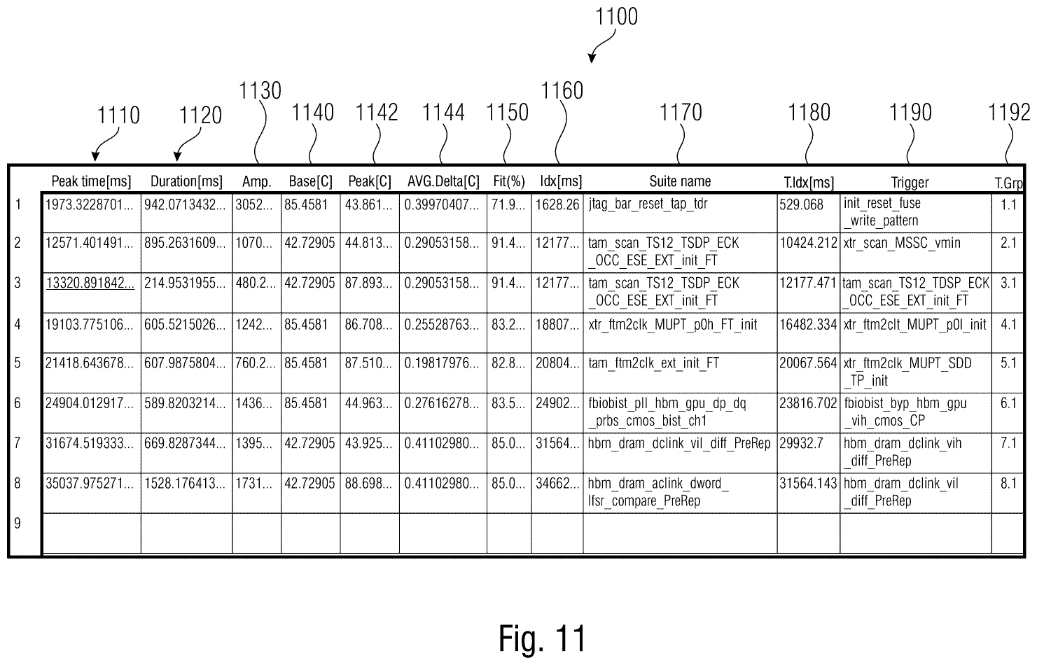

FIG. 11 shows a graphical representation of data provided by an embodiment of the present invention, e.g. by an automated test equipment according to the present invention. The table of FIG. 11 shows, for example, a peak time information 1110, a duration information 1120, an amplitude information 1130, a base temperature information 1140, a peak temperature information 1142, an average delta temperature information 1144, a fitting quality information 1150, an index time information 1160, a suite name information 1170, a time index information 1180, a trigger information 1190 and a trigger group information 1192.

For example, the peak time information, the duration information, the amplitude information, the base temperature information, the peak temperature information and the average delta temperature information may describe fitting functions which are fitted to the test profile. Fit quality information 1150 may, for example, describe a quality of the fitting, i.e., may describe how good the fitting function fits the testing profile.

The index time information 1160 may, for example, describe a starting time of a test suite (described by the suite name information 1170) which is executed at the peak time of a fitting function (or at a beginning of the fitting function). The index time information 1160 and the suite name information 1170 may, for example, be derived from the test log file on the basis of the peak time information 1110. Thus, the automated test equipment may provide the index time information 1160 and the suite name information 1170 using an analysis of the test log file and taking into consideration the peak time information 1170 that has been determined by the curve fitting. The trigger time index information 1180 may, for example, describe a time at which a trigger instruction is inserted into a test flow. For example, the trigger instruction may be inserted into the test flow, for example, right before a call of a test suite that is executed at the time of the peak of the fitting function (or at the time of the beginning of the fitting function). However, in other cases, the trigger instruction may be inserted into the test flow even earlier, i.e., not directly before the beginning of the test suite that is executed at the time of the peak of the fitting function (or at the time of the beginning of the fitting function), but before a call of an earlier test suite. For example, for the first peak shown in FIG. 11, a test suite called “jtag_bsr_reset_tap_tdr” may be executed at the time of the peak of the fitting function (or at the time of the beginning of the fitting function). However, a trigger command (e.g., a temperature control instruction) may be inserted into the test flow before a call of the test suite “init_reset_fuse_write_pattern”.

However, the peak of the second fitting function (or the beginning of the second fitting function) may occur during the execution of the test suite “tam_scan_TS12_. . .”, and the corresponding trigger function (e.g., temperature control instruction) may be inserted before the call to an earlier test suite “xtr_scan_MSSC_vmin”. However, the peak of the third fitting function (or the beginning of the second fitting function) may also occur during the test suite “tam_scam_TS12_. . .”, and the corresponding trigger may, for example, be inserted right before the call to said test suite “tam_scam_TS12_. . .”.

Thus, it can be seen that the automated test equipment may be configured to insert triggers (or trigger commands), which trigger a cooling operation, into a test flow on the basis of an information about a temperature peak (e.g., in dependence on parameters of fitting functions approximating the temperature peaks) and also using a test log information (e.g., an EDL file) which describes which tests or test suites are executed at which time.

In the following, aspects of the concept as described taking reference to FIGS. 8, 9, 10 and 11 will be briefly summarized.

In particular, FIG. 8 shows a schematic representation of a graphical user interface, which can be used in embodiments according to the invention. For example, FIG. 8 shows a graphical representation of a user friendly interface “RH7.4”.
for loading thermal profile and EDL data
for auto detection of peaks
program new test flow and handler for pre-cooling events.

In other words, the graphical user interface according to FIG. 8 may provide the user the possibility to load a thermal profile and (optionally) EDL data. Moreover, the graphical user interface may allow the user to set parameters for an auto-detection of peaks. For example the graphical interface also allows the user to decide which parameters should be determined automatically and which parameters should be manually entered by the user. Moreover, the graphical user interface allows the user to program new test flow and handler for pre-cooling events. For example, cooling triggers may be inserted into a test flow, and the handler may be provided with cooling information describing how the handler should react to a trigger.

In the following, the graphical interface and the mathematical module (which may, for example, be used in any of the embodiments of the present invention) will be described in some more detail. Taking reference, for example, to FIG. 9, the following may be available after loading the thermal profile and test flow data to the software (for example, to the software of the automated test equipment). For example, a curve 920, red curve, represents a thermal profile with problematic peaks. Moreover, a second curve (portions of which are designated with 932a, 932b, 932c, 932d, 932e, 932f, 932g, 932h; blue curve) shows mathematically auto-calculated “fitted peaks” (e.g. fitting curves), for cooling on a next test flow run. Moreover, text labels (e.g., blue text labels), e.g. designated with 942a, 942b, 942c, 942d, 942e, 942f, 942g, 942h, represent test suites that will be used for triggering to achieve cool-down in time.

Moreover, “X” markers show, for example, a start of cool down.

In the following, further details of the graphical user interface and/or the mathematical module will be described taking reference to FIGS. 10a and 10b.

According to an aspect of the invention, after loading the thermal profile and test flow data to the software (e.g., to the software of the automated test equipment), a user can also edit which other peaks to include via adapting filters, wherein, for example, real time identification of these (e.g. of these temperature peaks) is done when editing.

In the following, a further description of the graphical user interface and/or mathematical module will be provided taking reference to FIG. 11. According to an aspect of the invention, each cooling peak timing/duration and strength is extracted (e.g. by the automated test equipment) from (or by) the mathematical module (shown here, for example, in the GUI table of FIG. 11).

To conclude, embodiments according to the invention are related to a software implementation. For example, according to an aspect, a software implementation uses smart algorithms that characterize with a click of a button which thermal events are deviating and programs the handler when to trigger a cool down-event, for how long and how strong.

In the following, it will be described how an automation, e.g. an iterative determination of temperature control instructions, can be controlled using a user interface

It should be noted that the functionalities which are described taking reference to a user interface can naturally also be implemented using a different user interface. Moreover, it should be noted that it is naturally possible to implement only a subset of the functionalities and user interface items in embodiments according to the invention.

FIG. 14 shows a graphic representation of a user interface, which can optionally be used in combination with any of the embodiments of the present invention. The user interface may, for example, allow a user to control one or more automation settings. for example with respect to an iterative determination of the temperature control instructions (or of a test flow that comprises the temperature control instructions).

Generally, it should be noted that the automation settings, which are shown in FIG. 14, can be used to control one or more iterations for a step-wise determination and improvement of temperature control parameters.

For example, the graphical user interface 1400 according to FIG. 14 may comprise a setting 1420 which is titled “Reset Number of Runs For Triggered Logs” and which allows to change a number of times a test flow is run for each iteration. For example, according to an aspect of the invention, a test flow may even be run multiple times (by the automated test equipment) during a single iteration, for example to average-out fluctuations of the temperature profile and/or non-deterministic behavior.

Setting 1422, which is titled “Use EDL Data for Triggered Logs Evaluation” may be provided by a user and may, for example, decide whether EDL data are included or excluded for a training (e.g. for a determination of thermal peaks and/or for a determination of temperature control commands).

Moreover, setting 1424 titled “Save Session as Package after Each Log Cycle” may decide whether to save (e.g. whether the automated test equipment automatically saves) automatic execution data after each log iteration cycle. For example, the setting 1424 may be used to decide whether intermediate data (e.g. automatic execution data after each log duration cycle) should be saved for a later analysis or whether such a saving should be omitted.

Moreover, a user may be enabled to make a plurality of adjustments regarding iteration behavior. Accordingly, the iteration behavior of the automated test equipment may be adapted.

For example, a user may select between a “single log mode”, and a “continuous log mode”. For example, a setting 1432 may enable the single log mode, and setting 1434 may enable the continuous log mode (wherein the continuous log mode may, for example, auto-determine a completion).

For example, when operating in the single log mode, the automated test equipment may run a single log iteration, e.g. without user interaction, e.g. using the settings specified in a main graphical user interface. The single log iteration may, for example, comprise the following steps:

Load test flow, run test flow (e.g. by performing a test of the device under test under the control of the test flow), load thermal profile (e.g. a thermal profile recorded during the run of the test flow), load EDL data (e.g. data indicating which test program or test suite has been executed at which time during the run of the test flow), do analysis and decision for optimizing next iteration (e.g. analyzing how the previously determined temperature control instructions should be modified to obtain an improved result and/or deciding whether a current result or thermal profile is already good enough, e.g., with respect to a predetermined quality measure or quality criteria, such that no more further iteration is needed, or whether the temperature control instructions should be further improved because the current thermal profile does not yet fulfill a quality criteria or a quality measure), prepare new test flow (e.g. by inserting updated temperature control instructions into the test flow or by replacing previously determined temperature control instructions updated temperature control instructions), prepare new parameters for the handler (e.g. loading parameters of temperature control instruction into the handler).

For example, when operating in the continuous log mode, a tester may be configured to continuously run an iteration. For example, the steps described above with respect to the single log mode may be repeated one or more times. For example, when operating in the continuous log mode, the automated test equipment may automatically determine a completion e.g. by determining whether the current thermal profile obtained by the execution of a current test flow fulfills a quality measure or quality criterion. However, the continuous log mode may also be limited by a setting of a maximum total number of log iterations.

For example, a maximum total number of log iterations setting 1436, which is provided by a user, or which may be automatically determined by the automated test equipment, may limit the maximum number of iterations that the software of the automated test equipment can run for optimizing. Generally speaking, according to an aspect, it is possible to manually set the maximum iteration (or the maximum number of iterations) the software can run for optimizing using the maximum total number of log iterations setting 1436.

However, it should be noted that the maximum total number of log iterations may also be automatically determined by the automated test equipment. For example, the maximum total number of log iterations may be automatically determined by the automated test equipment on the basis of a determination of a number of “events”, e.g. in dependence on a number of temperature peaks (e.g. exceeding a certain threshold value and/or exceeding one or more relevance criteria).

For example, according to an aspect, the maximum total number of log iterations may be obtained (e.g. automatically by the automated test equipment) by multiplying a number of events (e.g. a number of events identified by the automated test equipment) with a predetermined (e.g. fixed or user-adjustable) factor.

For example, according to an aspect, a setting 1438 titled “Set Max. log Iterations to Event Num. X” may be provided in the graphical user interface. The “Set max. log iteration to event num. X” setting may, for example, set the maximum iteration (or the maximum number of iterations) (e.g. the maximum number of iterations which is automatically determined by the automated test equipment) to be proportional to the number of events that are being optimized times a number of choice (e.g. one and above, wherein, for example, decimals may optionally be allowed).

In other words, the setting “Set max. log iteration to event num. X” setting may be a factor by which a number of identified events (e.g. identified automatically by the automated test equipment, e.g. in a first iteration) is multiplied (e.g. by the automated test equipment) to obtain the maximum total number of log iterations. For example, a user may select whether the maximum total number of log iterations is set manually (e.g. as an absolute number), or whether the maximum total number of log iterations is determined automatically by the automated test equipment on the basis of a number of events (e.g. identified by the automated test equipment) and on the basis of a factor which may be set manually.

Optionally, the graphical user interface may comprise a setting 1440 titled “Overwrite Flow (org. to final trg.−reloaded inc)” which may determine a handling of the test flow. For example, a user may select whether to override (e.g. whether the automated test equipment automatically overwrites) a production test flow with the modified one which contains the “correct” trigger settings (e.g. temperature control instructions obtained by the automated test equipment). In this way, once the learning iteration is over and copy has been done, production will already launch the optimized thermal test flow.

In other words, a user may, for example, select whether an initial test flow should be automatically overwritten (e.g. by the automated test equipment), such that the resulting test flow, which is then used for a production test, is the result of the iteration.

Optionally, for this, a user can tailor select which iteration criteria is of interest (e.g. for the automatic selection which test flow out of a plurality of test flows should be used for the production test) (wherein, for example, one or more of the following options may optionally be implemented):
1. Use last trigger flow iteration (e.g. use a test flow obtained in a last iteration)
2. Use trigger flow iteration with min. (minimum) remaining events (e.g. use a test flow with a minimum number of remaining temperature peaks)
3. (Check box or functionality may optionally be added): use trigger flow with lowest average temperature above guard band
4. (Check box or functionality may optionally be added): use trigger flow with highest average temperature below guard band
5. (Check box or functionality may optionally added): use trigger flow with lowest maximum temperature above guard band
6. (Check box or functionality may optionally be added) use trigger flow with highest minimum temperature below guard band.

It should be note that, for example, in the case that a number of iterations fulfill one of these criteria, then the next criteria is used from within the group.

Generally speaking, for example, a plurality of criteria may be evaluated in a hierarchical order by the automated test equipment for the selection of a test flow.

For example, if there are minimum remaining events in iteration number #11 and #12 and #13, then select from these the one that has the lowest average temperature above guard band. For example, if this has also more than one, then continue to next criteria.

To conclude, for example, the automated test equipment may use one or more criteria to select a test flow, out of plurality of test flows that have been executed when iteratively determining the temperature control parameter, for later use. For such a selection, the automated test equipment may use one or more of the before mentioned criteria, wherein the user interface 1400 may optionally provide the user of the automated test equipment with the possibility to select which one or more criteria should be applied.

Just as an example, a selection item 1442 titled “Use Last Trigger Flow Iteration” may indicate that a last test flow of a sequence of test flows (which may be executed in an iterative determination of the temperature control instructions) should be selected for later use. Such a selection may, for example, be founded by the assumption that the test flows iteratively get better.

As another (alternative or additional) criterion, the automated test equipment may determine which test flow out of a plurality of test flows that have been executed during an iterative determination (ideally improvement) of temperature control instruction results in a minimum number of remaining events (e.g. remaining temperature peaks exceeding a threshold value). Such a selection criterion may, for example, be selected by a selection item 1444 titled “Use Trigger Flow Iteration with Minimum Remaining Events”. Accordingly, a respective test flow may be selected for a further use if this criterion is selected by a user of the automated test equipment (e.g. via user interface 1400).

As a further alternative, the automated test equipment may select a test flow with a lowest average temperature above a guard band for a further use. For example, the automated test equipment may analyze the temperature profile and quantitatively evaluate situations during which the dut temperature exceeds a predetermined maximum value, which may be considered as an upper limit of a so-called “guard band” (wherein, ideally, the dut temperature should be kept to within set “guard band”). Thus, the automated test equipment may determine a quantitative (e.g., numeric) information how strongly a dut temperature exceeds and upper limit of a desired temperature range (e.g. of a guard band) and use this information as a criterion for the selection of a test flow (e.g. for the selection of a test flow in which the upper limit of the desired temperature range is only exceeded to a small degree (e.g. by a small value and/or for short time, or a combination thereof)).

Similarly, the automated test equipment may, for example, obtain a quantitative information by how much a dut temperature lies below a lower limit of a desired temperature range for a plurality of test flows and use this information as a criterion to select a test flow for a later use.

Alternatively or in addition, the automated test equipment may determine, for a plurality of different test flows, a maximum temperature above a desired temperature range (e.g. a guard band) and use this maximum temperature above the desired temperature range as a criterion for selecting a test flow for a later use.

Alternatively or in addition, the automated test equipment may determine, for a plurality of test flows, a minimum temperature below a desired temperature range (e.g. below a guard band) and use this minimum temperature as a criterion to select a test flow for a later use.

Moreover, the user interface 1400 may, for example, comprise a possibility to select one or more of the above-mentioned criteria (or even other criteria) which are used for the selection of the test flow for a later use. For example, the automated test equipment may determine a ranking of the application of multiple selected criteria, and/or the user may optionally have an impact on said ranking of the criteria. Alternatively, however, a predefined ranking may be used.

In the following, the (optional) corrective action behavior of the automated test equipment will be described. It should be noted that the corrective action behavior may, at least partially, be controlled via the user interface 1400. However, in embodiments, one or more of the aspects of the corrective action behavior mentioned in the following may be implemented in the automated test equipment, for example in a fixed or configurable manner.

For example the automated test equipment may be capable to re-run (or may be configured to automatically re-run) a test flow if a test time deviates from a reference test time (e.g. from an original test time; e.g. from test time in a first iteration) by more than a predetermined allowable deviation.

For example, the selection item 1446 titled “Re-run Test Flow for Test Time Deviating from org.” (e.g. from an original test time) may be provided in the user interface 1400. Activation of this selection item may, for example, cause the automated test equipment to check if the iteration flow test time (e.g. a test time of a most current test flow execution) is larger compared to the original flow test time by the specified percentage (“Ensure Time Test Deviation not Above”). If so, the test flow is re-run (e.g. automatically re-run by the automated test equipment) until the condition is met (e.g. until the deviation of current test time from an original test time is not above a specified deviation) or the “re-run test-flow number” is maxed out (e.g. the specified number of allowable re-runs is reached).

In other words, the automated test equipment may, for example, compare a test time (e.g., a time needed for an execution of a test flow of a current iteration) with a reference test time (e.g., an original test time of a reference test flow). If the automated test equipment decides that the test time for the execution of the current time test flow deviates from the reference test time by more than a predetermined deviation (which may, for example, be specified by an entry field 1450, for example, in relative terms), the automated test equipment may (automatically) re-run the current test flow by a maximum number of times, wherein the maximum number of times may be specified by a setting 1448. The automated test equipment may try to arrive at an execution of the current test flow such that a test time is sufficiently close to the reference test time. For example, if the automated test equipment does not arrive at an execution of the current test flow with a test time that is sufficiently close to the reference test flow, an error message may be provided and/or a current test flow may be discarded and/or the current test flow may be modified. However, different handling is also possible.

Moreover, the automated test equipment may, optionally, have a mechanism to handle temperature peaks which have been well-approximated. For example, if a temperature peak has been eliminated in a given number of iterations, the automated test equipment may disable a further change of temperature control parameters that are related to such a temperature peak.

For example, the user interface 1400 may comprise a selection item 1452 titled “turn-off apply 1 by 1 after elim”, and may, for example, comprise a setting 1454 of a numeric value. For example, the “turn-off apply 1 by 1 after elim” selection item may enable and disable the following mechanism:

For example, once a peak has been fully eliminated by training (wherein fully eliminated means, for example, the temperature is inside the guard band), the program (e.g. which is executed by the automated test equipment) will start counting how many times in each iteration it has been in the eliminated status-if it has been eliminated sequentially the specified number of times (for example, by the number of times indicated by the selection 1454) in the graphical user interface GUI (for example, in the example of FIG. 14, “2”)—then the parameters for cooling this peak will be locked (for example, will not change anymore, or will not be changed anymore by the automated test equipment).

The point of the feature is that there can be minor device fluctuations between the iteration runs, which can result in the temperature not fully inside the guard band (slight deviations) and the program might try to continue to optimize when not necessary—in this manner once a safety criteria defined by the user (or predefined in the automated test equipment) (for example, two or more times eliminated) is reached, parameters are locked.

The feature may, for example, apply the locking in a “domino” effect-meaning that the first event (which occurred first in the sense of time) needs to be locked for the second events (which occurred afterward) to be locked with the specified criteria, and so on. For example, parameters for eliminating a subsequent event (for example, a subsequent temperature peak) would only be logged after the parameters for eliminating a proceeding event (e.g., a preceding temperature peak) are logged.

For example, locking parameters for the elimination of an event (e.g., locking temperature control instructions for the elimination of a temperature peak) when the temperature peak has been eliminated (e.g., reduced sufficiently to be within a predetermined temperature range, which may also be designated as a “guard band”) for a certain number of test flow executions and/or for a certain number of iterations helps to reduce a computational complexity and also helps to avoid a “overfitting”. For example, once parameters of a first temperature control instruction are “locked”, the determination of parameters of a subsequent second temperature control instruction may be facilitated, since a mutual impact between the temperature control instructions associated with the first temperature peak and the temperature control instructions associated with the subsequent second temperature peak is avoided by the fixing the parameters of the first temperature control instructions. Thus, the described concept may provide a significant advantage.

Moreover, the automated test equipment may optionally comprise an “enforce full superposition for lock” mechanism, which can, for example, be enabled and disabled by a selection item 1456. In the following, the “enforce full superposition for lock” mechanism will be briefly described. For example, for Gaussian functions, which are superposition of more than one (where each superposition corresponds to one peak event”, the count of fully eliminated have to apply for all events in the superposition before the lock is applied.

For example, if two or more adjacent (or closely adjacent) temperature peaks are approximated by a superposition of two or more Gaussian functions (or other approximation curves), the “lock” of temperature control instruction parameters may only be applied (by the automated test equipment) when all events (e.g., temperature peaks) in the superposition fulfill the above-mentioned “fully eliminated” criterion when the “enforce full superposition for lock” functionality is enabled. However, this mechanism may optionally be enabled or disabled.

In the following, some optional application window behavior mechanisms will be described, wherein it should be noted that the application window behavior characteristics may, for example, be configured via the graphical user interface 1400.

For example, the selection item 1460 titled “show all notification prompts” may decide whether the automated test equipment displays notifications during an automation mode. For example, if the selection item “show all notification prompts” is checked, this needs a user to acknowledge. Accordingly, the “show all notification prompts” selection item should be kept unchecked during automation mode. However, showing the notification prompts may allow for a maximum user involvement.

A selection item 1462 titled “relocate automation window when executing” may, for example, affect a positioning of an automation window. For example, activation of the “relocate automation window when executing” selection item 1462 may cause the automation window to move to the top left corner (or to any other predetermined position) so that a main graphical user interface and graph are still visible and not disturbed. Thus, the selection item 1462 may improve a user experience.

Selection item 1464 titled “Expand Automation Window on Open” may cause the automated test equipment to expand an automation window to display more data when executing. Thus, a maximum information can be provided to a user.

Selection item 1464 titled “Terminate app. On completion [continuous only]” may cause the automated test equipment to exit an application once an iteration learning is finished.

Selection item 1466 titled “Prompt msg. on completion [continuous only]” may cause the automated test equipment to notify a user that a learning iteration is finished. This may facilitate a user interaction.

Moreover, an automation mode button 1470 may allow a user to launch an automation window, e.g., to start an iterative determination of temperature controlled instructions.

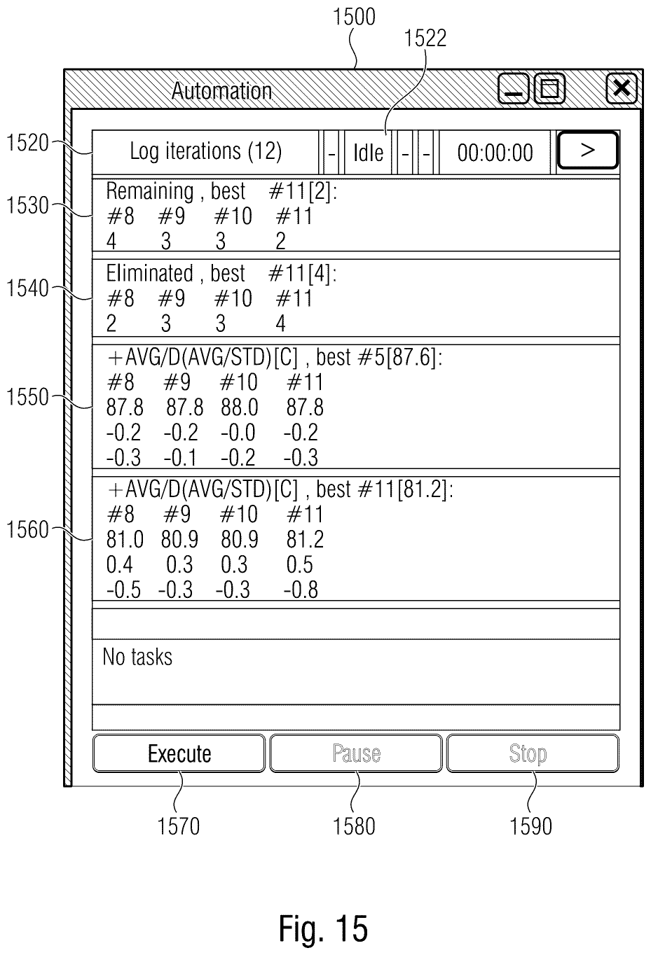

In the following, an automation window, which may optionally be used in embodiments according to the present invention, will be described. FIG. 15 shows a representation of such an automation window. The automation window may, for example, be displayed during an execution of test flows (e.g. during an iterative execution of test flows). However, alternatively or in addition, the automation window may be displayed to user by the automated test equipment after an iteration is completed. For example, the automation window may show, at a reference numeral 1520, a total number of log iterations. In the present case, 12 iterations have been executed, which are numbered with #0 to #11. Moreover, the automation window 1500 may, for example, indicate a status, which is shown at reference numeral 1522. In the present case, the status is “idle”, but the automation window may also display intermediate results during an (iterative) execution of the test flows.

For example, automation window 1500 may display one or more “performance metrics” or “quality metrics” for the iterations, wherein, for example, only those iterations that comprise the best performance metrics may be displayed. For example, an indication “remaining best #X1[Y1]” may be shown, e.g. as indicated at reference numeral 1530. In this case, X1 may be the iteration number, and Y1 may be the number of peaks remaining. Thus, the automation window 1500 may display how many peaks are remaining in which iteration, and may also provide information which iteration brings along the best results. In the present case, four peaks are remaining in iteration #8, three peaks are remaining in iterations #9 and #10, and two peaks are remaining in iteration #11. Accordingly, the automated test equipment can recognize that iteration number #11 brings along a best result in terms of remaining peaks (e.g. temperature peaks).

Moreover, the automation window 1500 may, for example, display a number of eliminated peaks (e.g. temperature peaks). For example, the information “eliminated best #X2[Y2]” may provide such an indication. Here, X2 may be the iteration number, and Y2 may be the number of peaks eliminated. This is illustrated at reference numeral 1540. For example, it may be displayed in the automation window how many peaks have been eliminated in which iteration, and it may also be displayed which iteration brings along a best possible result. For example, it can be seen that two peaks have been eliminated in the iteration #8, that three peaks have been eliminated in the iterations #9 and #10, and that four peaks have been illuminated in iteration #11. Accordingly, automated test equipment can determine that iteration #11 brings along a best possible result in this respect.

Moreover, the automation window 1500 may indicate an average temperature above an upper guard band, an improvement of this average temperature and a standard deviation (or an improvement of the standard deviation). For example, these results may be displayed as an information “+AVG D [ADV/STD[C] #X2[Y3]: X” or “+AVG D (AVG/STD)[C] #X2[Y3]: X”. This is shown, for example, at reference numeral 1550. For example, the following data X may be displayed,
1. The average temperature above the upper guard-band per iteration;
2. the average temperature per iteration minus [delta] the average temperature of the original test flow above the guard band;
3. the standard deviation temperature per iteration minus [delta] the standard deviation temperature of the original test-flow above the upper guard band.

Moreover, “best” may indicate the lowest average above the upper guard band.

In other words, the automated test equipment may evaluate and display, in the automation window 1500, the average temperature above the upper guard band per iteration.

Moreover, the automated test equipment may determine by how much this average temperature above the upper guard band is reduced in different iterations when compared to a reference value (for example, the average temperature of the original test-flow above the guard band).

Moreover, the automated test equipment may also determine by how much the standard deviation temperature is reduced when compared to a reference standard deviation temperature (e.g. a reference standard deviation temperature of an original test flow above the upper guard band).

Thus, it is apparent for the user by how much the average temperature above the guard band is reduced in different iterations and/or by how much the standard deviation temperature (e.g. above the upper guard band) is reduced in different iterations.

Moreover, the automated test equipment may also determine, and display in the automation window 1500, a “best” information, which indicates the lowest average above the upper guard bands. For example, as can be seen in FIG. 15 at reference numeral 1550, the average temperature above the guard band may be 87.8 degrees in iterations #8 and #9 and #11, and the average temperature above the guard band may be 88.0 degrees in iteration #10. Thus, the average temperature above the upper guard band may be reduced by 0.2 degrees in iterations #8, #9 and #11, while there is no reduction in iteration #10. However, a best case may be given in iteration #5, where an average temperature above the guard band of 87.6 degree is reached.

Moreover, the automated test equipment may also determine an average temperature below the lower guard band per iteration, as can be seen at reference numeral 1560. For example, information “−AVG/D[ADV/STD[C]#X2[Y3]:X” or “−AVG/D (AVG/STD)[C]#X2[Y3]:X” may be provided. For example, the following data may be displayed:
1. The average temperature below the lower guard band per iteration;
2. the average temperature per iteration minus [delta] the average temperature of the original test flow below the lower guard band; and
3. the standard deviation temperature per iteration minus [delta] the standard deviation temperature of the original test flow below the lower guard band.

However, it should be noted that determination and display of this information should be considered as being optional, and that only some of the information items may be determined and/or displayed in some embodiments.

Moreover, regarding a detailed discussion, reference is made to the above discussion of the average temperature above the upper guard band, since the above explanation also apply for a determination of a temperature below the guard band.

For example, a “best” information may also be indicated, wherein the “best” information indicates, for example, the highest average below the lower guard band.

To conclude, a user can monitor one or more quality criteria which can be reached in different iterations, for example, with respect to a remaining number of temperature peaks and/or with respect to an average temperature above the guard band and/or with respect to an average temperature below the guard band. This may, for example, help the user to select an appropriate test flow for a production test.

Moreover, it should be noted that the automation window 1500 may, for example, also allow for a control of the operation. For example, a “execute” button 1570 may allow the user to start an automating mode run, a “pause” button 1580 may allow the user to pause execution and a “stop” button 1590 may allow the user to stop execution.

To conclude, the automation window may, for example, present quality information with respect to iterations to the user (e.g. during an execution of a sequence of test flows or after an execution of a sequence of test flows) and may also provide the user with control over the execution of the iterations.

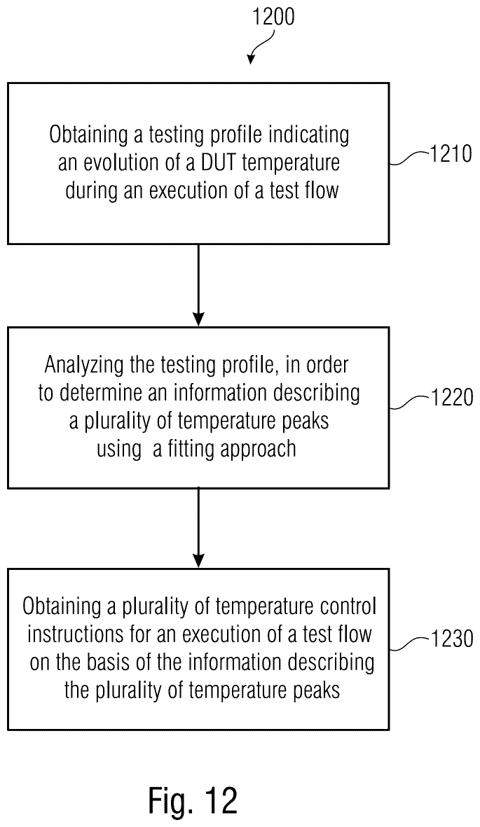

### Method According to FIG. 12

FIG. 12 shows a flow chart of a method 1200, according to an embodiment of the present invention.

The method 1200 comprises obtaining 1210 a testing profile indicating an evolution of a DUT temperature during an execution of a test flow.

The method 1200 also comprises analyzing 1220 the testing profile, in order to determine an information describing a plurality of temperature peaks using a fitting approach.

The method 1200 also comprises obtaining 1230 a plurality of temperature control instructions for an execution of a test flow on the basis of the information describing the plurality of temperature peaks.

It should be noted that the method 1200 according to FIG. 12 may optionally be supplemented by any of the feature, functionalities and details disclosed herein (also with respect to apparatuses), both individually and taken in combination. Moreover, it should be noted that any of the features, functionalities an details of the method 1200 may optionally be introduced into any of the other embodiments disclosed herein, both individually and taken in combination.

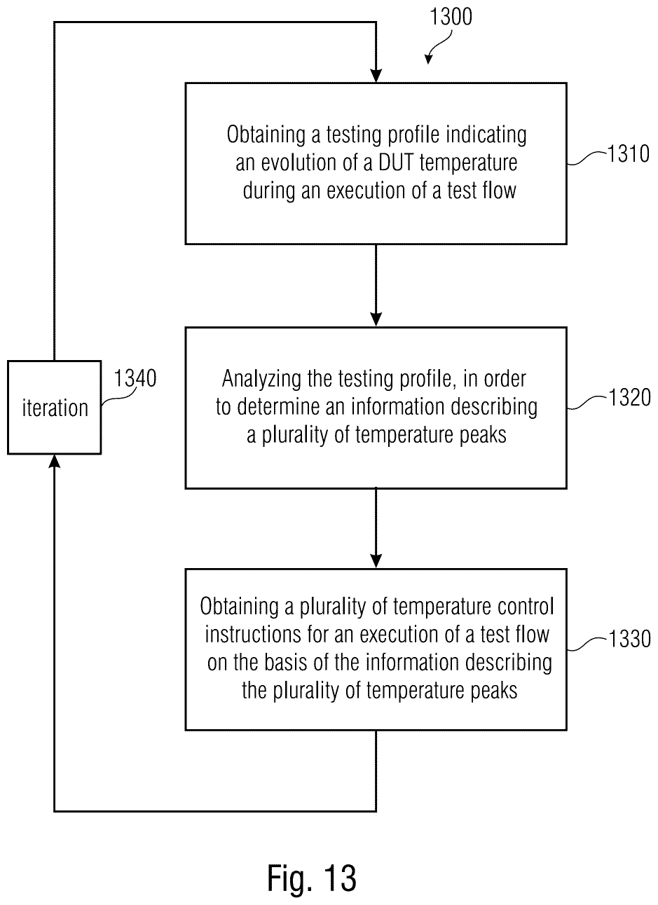

### Method According to FIG. 13

FIG. 13 shows a flow chart of a method 1300, according to an embodiment of the present invention.

The method 1300 comprises obtaining 1310 a testing profile indicating an evolution of a DUT temperature during an execution of a test flow.

The method 1300 also comprises analyzing 1320 the testing profile, in order to determine an information describing a plurality of temperature peaks.

The method 1300 also comprises obtaining 1330 a plurality of temperature control instructions for an execution of a test flow on the basis of the information describing the plurality of temperature peaks.

Moreover, the method 1300 comprises at least one iteration 1340, which means that steps 1310, 1320, 1330 are repeated, to thereby improve the temperature control instructions.

It should be noted that the method 1300 according to FIG. 13 may optionally be supplemented by any of the feature, functionalities and details disclosed herein (also with respect to apparatuses), both individually and taken in combination. Moreover, it should be noted that any of the features, functionalities an details of the method 1300 may optionally be introduced into any of the other embodiments disclosed herein, both individually and taken in combination.

### Implementation Alternatives

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

The methods described herein, or any components of the apparatus described herein, may be performed at least partially by hardware and/or by software.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. An automated test equipment, ATE, for testing a device under test, DUT, the automated test equipment comprising:
a testing profile analyzer; and
a temperature control instruction provider;
wherein the testing profile analyzer is configured to acquire a testing profile indicating an evolution of a DUT temperature during an execution of a given test flow;
wherein the testing profile analyzer is configured analyze the testing profile, in order determine an information describing a plurality of temperature peaks; and
wherein the temperature control instruction provider is configured to acquire a plurality of temperature control instructions for an execution of a test flow on the basis of the information describing the plurality of temperature peaks;
wherein the temperature control instruction provider is configured to iteratively acquire the temperature control instructions.

2. The automated test equipment according to claim 1, further comprising:
an iteration controller;
wherein the iteration controller is configured to control the automated test equipment to re-execute a determination of a plurality of temperature control instructions on the basis a testing profile at least one time,
wherein previously determined temperature control instructions are used when determining a testing profile for a current iteration.

3. The automated test equipment according to claim 1, further comprising:
a temperature control instruction inserter; and
an iteration controller;
wherein the temperature control instruction inserter is configured to acquire an updated test flow, which is based on the given test flow and into which the plurality of temperature control instructions are inserted, in a first iteration, and
wherein the iteration controller is configured to control the automated test equipment to execute the updated test flow, in order to acquire an updated testing profile for use in a second iteration, and
wherein the temperature control instruction inserter is configured to acquire a refined test flow on the basis of the updated testing profile in a second iteration.

4. The automated test equipment according to claim 1, further comprising:
a temperature control instruction inserter; and
an iteration controller;
wherein the iteration controller is configured to control the automated test equipment to execute an updated test flow, which is based on the given test flow and into which the plurality of temperature control instructions are inserted, and
wherein the a testing profile analyzer is configured to evaluate an updated testing profile indicating an evolution of a DUT temperature during an execution of the updated test flow; and
wherein the temperature control instruction provider t is configured to acquire refined temperature control instructions in dependence on the updated testing profile,
wherein the temperature control instruction inserter is configured to acquire a refined test flow comprising the refined temperature control instructions.

5. The automated test equipment according to claim 1,
wherein the testing profile analyzer is configured to determine the information describing the plurality of temperature peaks using a fitting approach.

6. The automated test equipment according to claim 5,
wherein the testing profile analyzer is configured to fit respective fitting functions to the plurality of temperature peaks within the testing profile, in order to acquire parameters of the temperature peaks.

7. The automated test equipment according to claim 6,
wherein the temperature control instruction provider is configured to determine the temperature control instructions in dependence on one or more parameters of the fitting functions.

8. The automated test equipment according to claim 1,
wherein the testing profile analyzer is configured to identify a plurality of temperature peaks in the testing profile using a temperature threshold value and/or to identify a plurality of temperature peaks in the testing profile in dependence on an extension of respective temperature peaks, and
wherein the testing profile analyzer is configured to fit respective fitting functions to the identified temperature peaks, or to a subset of the identified temperature peaks, in order to acquire the information describing the plurality of temperature peaks.

9. The automated test equipment according to claim 1,
wherein the testing profile analyzer or the temperature control instruction provider is configured to classify thermal events as thermal events comprising a small significance and as thermal events comprising a high significance; and
wherein the temperature control instruction provider is configured to acquire the temperature control instructions on the basis of thermal events comprising the high significance.

10. The automated test equipment according to claim 1,
wherein the testing profile analyzer is configured to take into account a minimum overheat event duration threshold value when determining the information describing the plurality of temperature peaks.

11. The automated test equipment according to claim 1,
wherein the testing profile analyzer is configured to fit a common fitting function to two or more adjacent temperature peaks within the testing profile.

12. The automated test equipment according to claim 11,
wherein the testing profile analyzer is configured to evaluate a maximum overheat event proximity parameter to decide whether the common fitting function should be fitted to the two or more adjacent temperature peaks within the testing profile.

13. The automated test equipment according to claim 1,
wherein the temperature control instruction provider is configured to acquire a combined temperature control event or a combined temperature control instruction on the basis of two or more fitted temperature peaks.

14. The automated test equipment according to claim 13,
wherein the testing profile analyzer or the temperature control instruction provider is configured to automatically adjust a criterion for acquiring the combined temperature control event or the combined temperature control instruction on the basis of the two or more fitted temperature peaks such that a total number of temperature control events or a total number of temperature control instructions does not exceed a predetermined maximum value.

15. The automated test equipment according to claim 1,
wherein the testing profile analyzer is configured to select a limited a number of thermal peaks, out of an overall number of thermal peaks within the testing profile, for a determination of the information describing the plurality of temperature peaks,
or wherein the testing profile analyzer or the temperature control instruction provider is configured to select a limited a number of thermal peaks, out of an overall number of thermal peaks within the testing profile, for the acquiring of the plurality of temperature control instructions.

16. The automated test equipment according to claim 1, further comprising:
a temperature control instruction inserter;
wherein the temperature control instruction inserter is configured to receive an input test flow and to insert the plurality of temperature control instructions into the input test flow, to acquire an updated test flow,
wherein the temperature control instruction inserter is configured to insert the temperature control instructions into the input test flow to start a temperature control before a beginning of a temperature peak.

17. The automated test equipment according to claim 16,
wherein the temperature control instruction inserter is configured to acquire a test log file which is associated with the thermal profile, and
wherein the temperature control instruction inserter is configured to insert the temperature control instructions into the test flow using information of the test log file.

18. The automated test equipment according to claim 1, further comprising:
a visualizer;
wherein the visualizer is configured to jointly visualize
the testing profile indicating the evolution of the DUT temperature during the execution of the given test flow, and
respective fitting functions fitted to the plurality of temperature peaks within the testing profile;
wherein the visualizer is configured to also visualize temperature control periods determined using the information describing the plurality of temperature peaks; and
wherein the visualizer is configured to update a visualization in response to a user interaction changing one or more parameters.

19. A method for testing a device under test, DUT, the method comprising:
acquiring a testing profile indicating an evolution of a DUT temperature during an execution of a given test flow;
analyzing the testing profile, in order determine an information describing a plurality of temperature peaks; and
acquiring a plurality of temperature control instructions for an execution of a test flow on the basis of the information describing the plurality of temperature peaks; and
wherein the temperature control instructions are acquired iteratively.

20. A non-transitory digital storage medium having a computer program stored thereon to perform a method for testing a device under test, DUT,
wherein the method comprises acquiring a testing profile indicating an evolution of a DUT temperature during an execution of a given test flow;
wherein the method comprises analyzing the testing profile, in order determine an information describing a plurality of temperature peaks; and
wherein the method comprises acquiring a plurality of temperature control instructions for an execution of a test flow on the basis of the information describing the plurality of temperature peaks; and
wherein the method comprises iteratively acquiring the temperature control instructions,
when said computer program is run by a computer.
